(19) United States
(12) Patent Application Publication
(10) Pub. No.: US 2024/0237359 A1
(43) Pub. Date: Jul. 11, 2024

(54) SYSTEM-ON-A-CHIP (SOC) INTEGRATION OF RESISTIVE RANDOM-ACCESS MEMORY DEVICES WITH VARYING SWITCHING CHARACTERISTICS

(71) Applicant: TetraMem Inc., Fremont, CA (US)

(72) Inventors: Ning Ge, Danville, CA (US); Minxian Zhang, Amherst, MA (US); Mingche Wu, San Jose, CA (US); Gary Miner, Fremont, CA (US)

(73) Assignee: TetraMem Inc., Fremont, CA (US)

(21) Appl. No.: 18/152,072

(22) Filed: Jan. 9, 2023

(51) Int. Cl. H10B 63/00; H10N 70/00; H10N 70/20

(52) U.S. Cl. CPC H10B 63/84; H10B 63/30; H10N 70/063; H10N 70/253; H10N 70/841; H10N 70/8833

(57) ABSTRACT

An apparatus including a plurality of resistive random-access memory (RRAM) devices is provided. The RRAM devices are fabricated on a single substrate in some embodiments. The apparatus includes an interconnect layer fabricated on the substrate. A first RRAM device of the RRAM devices includes a first bottom electrode, a first top electrode; and a first filament-forming layer fabricated between the first bottom electrode and the first top electrode. A second RRAM device of the RRAM devices includes a second bottom electrode, a second top electrode, and a second filament-forming layer fabricated between the second bottom electrode and the second top electrode. The first bottom electrode and the second bottom electrode are fabricated on multiple metallic pads or metallic vias of the interconnect layer. The first filament-forming layer and the second filament-forming layer include different switching oxides.

### TECHNICAL FIELD

The implementations of the disclosure generally relate to resistive random-access memory (RRAM) devices and, more specifically, to homogenous SoC integration of Resistive Random-Access Memory (RRAM) devices with varying switching characteristics.

### BACKGROUND

A resistive random-access memory (RRAM) device is a two-terminal passive device with tunable and non-volatile resistance. The resistance of the RRAM device may be electrically switched between a high-resistance state (HRS) and a low-resistance state (LRS) by applying suitable programming signals to the RRAM device. RRAM devices may be used to form crossbar arrays for implementing varying applications, such as in-memory computing applications, non-volatile solid-state memory, image processing applications, neural networks, etc.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with one or more aspects of the present disclosure, an apparatus is provided. The apparatus includes: a first interconnect layer fabricated on a substrate, wherein the first interconnect layer includes a plurality of metallic interconnects; a first resistive random-access memory (RRAM) device and a second RRAM device. The first RRAM device includes a first bottom electrode fabricated on a first metallic interconnect of the first interconnect layer; a first top electrode; and a first filament-forming layer fabricated between the first bottom electrode and the first top electrode, wherein the first filament-forming layer includes a first switching oxide. The second RRAM device includes a second bottom electrode fabricated on a second metallic interconnect of the first interconnect layer; a second top electrode; and a second filament-forming layer fabricated between the second bottom electrode and the second top electrode, wherein the second filament-forming layer includes a second switching oxide that is different from the first switching oxide.

In some embodiments, the apparatus further includes a first etch stop layer fabricated on the first interconnect layer. In some embodiments, a first filament-forming region of the first filament-forming layer and at least a portion of the first top electrode are fabricated in a first via in the first etch stop layer. In some embodiments, a second filament-forming region of the second filament-forming layer and at least a portion of the second top electrode are fabricated in a second via in the first etch stop layer.

In some embodiments, the first etch stop layer includes at least one of silicon nitride or silicon oxynitride.

In some embodiments, the first metallic interconnect is connected to a first transistor. In some embodiments, the second metallic interconnect of the first interconnect layer is connected to a second transistor.

In some embodiments, the first switching oxide includes at least one of HfOₓ, TaOₓ, TiOₓ, NbOₓ, ZrOₓ, or SiO₂.

In some embodiments, the first RRAM device further includes an interface layer fabricated between the first top electrode and the first filament-forming layer, wherein the interface layer includes at least one of AlO₂, MgO, Y₂O₃, or La₂O₃.

In some embodiments, the first filament-forming layer does not include the second switching oxide.

In some embodiments, the apparatus further includes a second interconnect layer, wherein a first metallic interconnect of the second interconnect layer is fabricated on the first top electrode, and wherein a second metallic interconnect of the second interconnect layer is fabricated on the second top electrode.

In some embodiments, the first top electrode is connected to a first bitline of a first crossbar circuit, and wherein the second top electrode is connected to a second bitline of a second crossbar circuit.

In some embodiments, the first switching oxide includes TaOₓ, and wherein the second switching oxide includes HfOₓ.

In some embodiments, the first bottom electrode and the second bottom electrode comprise the same metallic materials.

In some embodiments, the apparatus further includes a third RRAM device fabricated on a third interconnect layer.

According to one or more aspects of the present disclosure, methods for fabricating an apparatus including a plurality of RRAM devices are provided. The methods include: fabricating a first bottom electrode of a first resistive random-access memory (RRAM) device and a second bottom electrode of a second RRAM device on a first metallic interconnect and a second metallic interconnect of a first interconnect layer, respectively, wherein the first metallic interconnect and the second metallic interconnect of the first interconnect layer are fabricated on a substrate; fabricating a first filament-forming layer and a first top electrode on the first bottom electrode, wherein the first filament-forming layer includes a first switching oxide; and fabricating a second filament-forming layer and a second top electrode on the second bottom electrode, wherein the second filament-forming layer includes a second switching oxide that is not included in the first filament-forming layer.

In some embodiments, the methods further include fabricating a first etch stop layer on the first interconnect layer and the substrate; fabricating a first via in the first etch stop layer to expose a portion of the first bottom electrode; and fabricating a second via in the first etch stop layer to expose a portion of the second bottom electrode, wherein at least a portion of the first filament-forming layer is fabricated in the first via, and wherein at least a portion of the second filament-forming layer is fabricated in the second via.

In some embodiments, the methods further include fabricating a dielectric layer in the second via, wherein one or more portions of the dielectric layer are fabricated on the first etch stop layer.

In some embodiments, fabricating the first filament-forming layer and the first top electrode on the first bottom electrode includes: fabricating a first switching oxide layer on the first etch stop layer, the exposed portion of the first bottom electrode, and the dielectric layer; fabricating a first top electrode layer on the first switching oxide layer; etching the first switching oxide layer; and etching the first top electrode layer.

In some embodiments, the dielectric layer includes silicon dioxide, and wherein the first etch stop layer includes at least one of silicon nitride, silicon oxynitride.

In some embodiments, fabricating the second filament-forming layer and the second top electrode on the second bottom electrode includes: fabricating a second etch stop layer on the first top electrode; removing the dielectric layer to expose the portion of the second bottom electrode; fabricating a second switching oxide layer on the first etch stop layer, the second etch stop layer, and the exposed portion of the second bottom electrode; fabricating a second top electrode layer on the second switching oxide layer; and etching the second top electrode layer and the second switching oxide layer.

In some embodiments, the methods further include fabricating a third etch stop layer on the second top electrode layer.

In some embodiments, the first metallic interconnect and the second metallic interconnect are fabricated on a single substrate.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating an example of a crossbar circuit in accordance with some embodiments of the present disclosure.

FIG. 2 is a schematic diagram illustrating an example of a cross-point device in accordance with some embodiments of the present disclosure.

FIG. 3A is a schematic diagram illustrating an example semiconductor device including RRAM devices with varying switching characteristics in accordance with some embodiments of the present disclosure.

FIGS. 3B, 3C, and 3D are schematic diagrams illustrating cross-sectional views of structures and processes for fabricating the semiconductor device of FIG. 3A.

FIGS. 4A-4O are schematic diagrams illustrating cross-sectional views of example structures for fabricating a semiconductor device including RRAM devices with varying switching characteristics in accordance with some embodiments of the present disclosure.

FIGS. 5A, 5B, 5C, 5D, and 5E are schematic diagrams illustrating cross-sectional views of structures relating to an example process for fabricating interconnect layers on the semiconductor of FIG. 4O in accordance with some embodiments of the present disclosure.

FIGS. 6A, 6B, 6C, 6D, and 6E are schematic diagrams illustrating cross-sectional views of example RRAM devices in accordance with some embodiments of the present disclosure.

FIG. 7A is a flowchart illustrating an example process for fabricating RRAM devices in accordance with some embodiments of the present disclosure.

FIG. 7B is a flowchart illustrating an example process for fabricating a first filament-forming layer and a first top electrode of a first RRAM device of the RRAM devices in accordance with some embodiments of the present disclosure.

FIG. 7C is a flowchart illustrating an example process for fabricating a second filament-forming layer and a second top electrode of a second RRAM device of the RRAM devices in accordance with some embodiments of the present disclosure.

FIG. 8 is a flowchart illustrating an example process for fabricating one or more interconnect layers in accordance with some embodiments of the present disclosure.

FIG. 9A is a flowchart illustrating an example process for fabricating an interconnect structure including a metallic via and a metallic pad in one process.

FIGS. 9B-9G illustrate cross-sectional views of structures for fabricating an interconnect structure by implementing the process of FIG. 9A in accordance with some embodiments of the present disclosure.

### DETAILED DESCRIPTION

Aspects of the disclosure provide resistive random-access memory (RRAM) devices and methods for fabricating the RRAM devices. An RRAM device is a two-terminal passive device with tunable resistance. The RRAM device may include a bottom electrode, a top electrode, and a switching oxide layer fabricated between the bottom electrode and the top electrode. The bottom electrode may include a nonreactive metal, such as platinum (Pt), palladium (Pd), etc. The top electrode may include a reactive metal, such as tantalum (Ta). The electrode including the nonreactive metal is also referred to herein as the “nonreactive electrode.” The switching oxide layer may include a transition metal oxide, such as hafnium oxide (HfOₓ) or tantalum oxide (TaOₓ). The RRAM device may be in an initial state or virgin state and may have an initial high resistance before it is subject to a suitable electrical stimulation (e.g., a voltage or current signal applied to the RRAM device). The RRAM device may be tuned to a lower resistance state from the virgin state via a forming process or from a high-resistance state (HRS) to a lower resistance state (LRS) via a setting process. The forming process may refer to programming a device starting from the virgin state. The setting process may refer to programming a device starting from the high resistance state (HRS). After the reactive metal electrode is deposited on the switching oxide, the reactive metal can absorb oxygen from the switching oxide layer and create oxygen vacancies in the switching oxide layer, and oxygen ions can migrate in the switching oxide through a vacancy mechanism. During a forming process, a suitable programming signal (e.g., a voltage or current signal) may be applied to the RRAM device, which may cause a drift of oxygen ions to migrate from the switching oxide to the reactive electrode. As a result, a conductive channel or filament may form through the switching oxide layer (e.g., from the reactive electrode to the nonreactive electrode). The RRAM device may then be reset to a high-resistance state by applying a reset signal (e.g., a voltage signal, a current signal) to the RRAM device. The application of the reset signal to the RRAM device may cause oxygen ions to migrate back to the switching oxide layer and may thus interrupt the conductive filament. The RRAM device may be electrically switched between a high-resistance state and a low-resistance state by applying suitable programming signals (e.g., voltage signals, current signals, etc.) to the RRAM device. In a crossbar array circuit, the programming signals may be provided to the designated RRAM device via a selector, such as a transistor or a diode.

RRAM devices may be used to implement varying applications, such as memory, in-memory computing, storage, logic circuitry, etc. RRAM devices with different switching characteristics (e.g., analog switching behaviors, operating voltage and/or current, cycling endurance, etc.) may be suitable to implement different applications and/or to perform different circuit functions. For example, unipolar RRAM devices that may store a single bit may be used for storage applications but may not be suitable for certain in-memory computing applications that require RRAM devices with multiple analog resistance levels. As another example, some memory applications may require RRAM devices with great endurance ability (e.g., single-bit endurance greater than 10 billion cycles). Some memory and in-memory computing applications may require RRAM devices with repeatable switches, multi-level analog behaviors, and desirable retention and/or read stability. A given type of RRAM device might not be able to present all of the characteristics required by a broad range of RRAM applications. The RRAM devices presenting different switching characteristics may include varying device structures and/or materials. Existing approaches for fabricating do not provide solutions for fabricating such RRAM devices on the same substrate to meet the requirements of various applications.

The present disclosure provides mechanisms for homogenous SoC integration of RRAM devices with varying switching characteristics on a single substrate. The RRAM devices may present different switching characteristics suitable for implementing multiple applications (e.g., memory, storage, in-memory computing, logic circuitry, etc.). In some embodiments, the RRAM devices may include different device stacks. For example, a first RRAM device may include a bottom electrode including TiN, a switching oxide layer including HfOx, and a top electrode including Ta. A second RRAM device fabricated on the substrate may include a bottom electrode including a bottom electrode including Pt, a switching oxide layer including TaOx, and a top electrode including Ta. In some embodiments, the second RRAM device may further include an interface layer including Al₂O₃ fabricated between the switching oxide layer and the top electrode of the second RRAM device. A third RRAM device may include a bottom electrode including Cu and/or CuO₂, a switching oxide layer including SiO₂, and a top electrode including Cu. In some embodiments, the first RRAM device, the second RRAM device, and the third RRAM device may be part of multiple crossbar arrays for performing different circuit functions and/or implementing different applications.

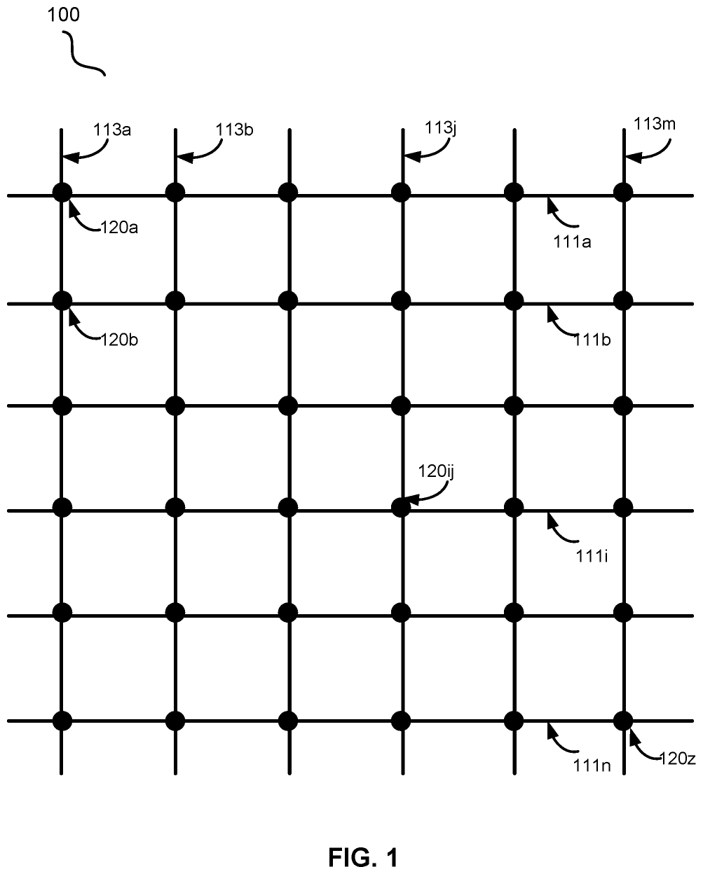

FIG. 1 is a schematic diagram illustrating an example 100 of a crossbar circuit in accordance with some embodiments of the present disclosure. As shown, crossbar circuit 100 may include a plurality of interconnecting electrically conductive wires, such as one or more row wires 111a, 111b, . . . , 111i, . . . , 111n, and column wires 113a, 113b, . . . , 113j, . . . , 113m for an n-row by m-column crossbar array. The crossbar circuit 100 may further include cross-point devices 120a, 120b, . . . , 120z, etc. Each of the cross-point devices may connect a row wire and a column wire. For example, the cross-point device 120ij may connect the row wire 111i and the column wire 113j. In some embodiments, crossbar circuit 100 may further include digital-to-analog converters (DAC, not shown), analog-to-digital converters (ADC, not shown), switches (not shown), and/or any other suitable circuit components for implementing a crossbar-based apparatus. The number of the column wires 113a-m and the number of the row wires 111a-n may or may not be the same.

Row wires 111 may include a first row wire 111a, a second row wire 111b, . . . , 111i, . . . , and an n-th row wire 111n. Each of row wires 111a, . . . , 111n may be and/or include any suitable electrically conductive material. In some embodiments, each row wire 111a-n may be a metal wire.

Column wires 113 may include a first column wire 113a, a second column wire 113b, . . . , and an m-th column wire 113m. Each of column wires 113a-m may be and/or include any suitable electrically conductive material. In some embodiments, each column wire 113a-m may be a metal wire.

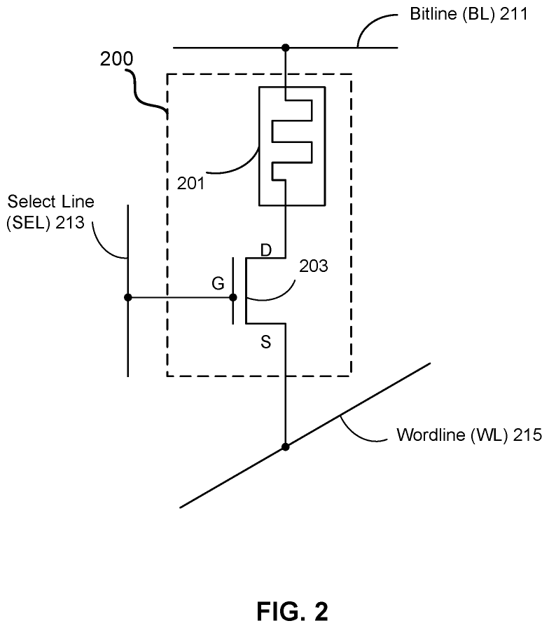

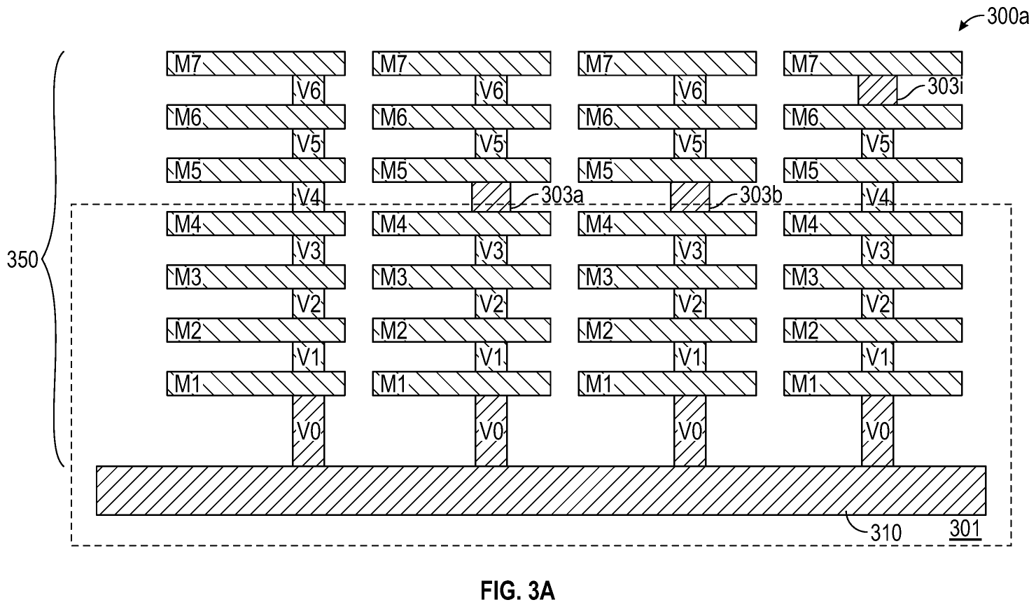

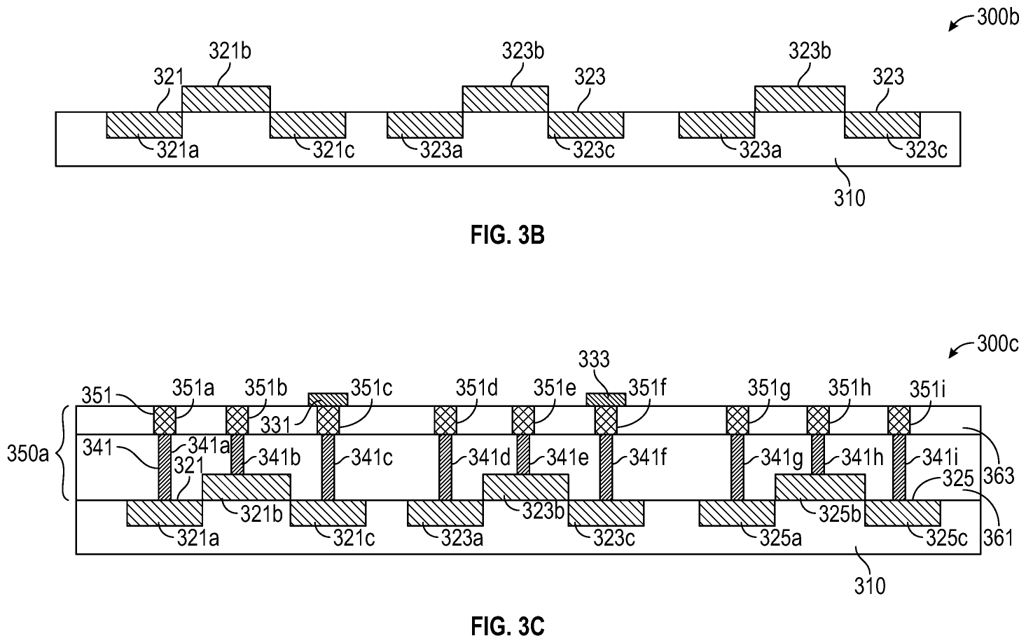

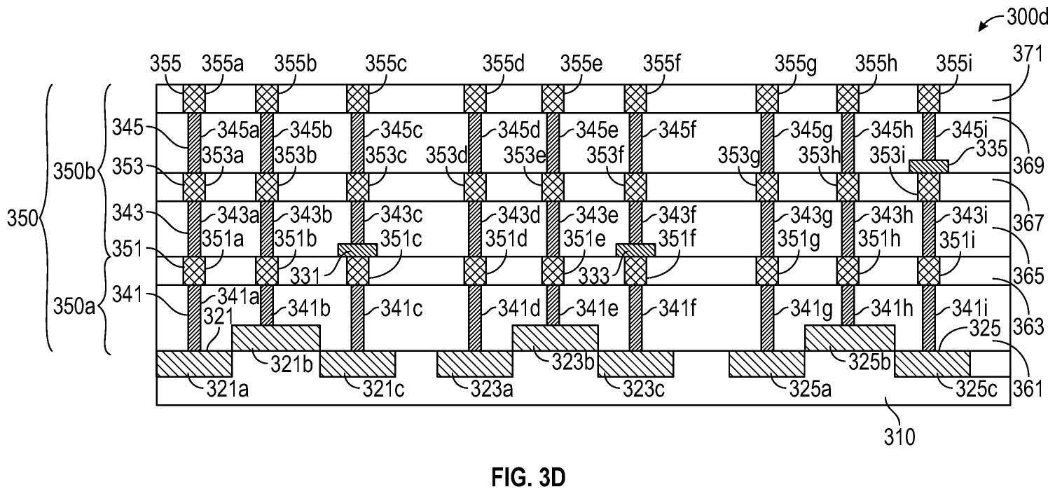

Each cross-point device 120 may be and/or include any suitable device with tunable resistance, such as a memristor, phase-change memory (PCM) devices, floating gates, spintronic devices, RRAM, static random-access memory (SRAM), etc. In some embodiments, one or more cross-point devices 120 may include an RRAM device as described in connection with FIGS. 3A-6E. In some embodiments, one or more cross-point devices 120 may be and/or include a cross-point device (a 1T1R configuration) as described in connection with FIG. 2 below. In some embodiments, one or more cross-point devices 120 may include a one-diode-one-resistor (1D1R) configuration that includes a unipolar RRAM connected to a diode.

Crossbar circuit 100 may perform parallel weighted voltage multiplication and current summation. For example, an input voltage signal may be applied to one or more rows of crossbar circuit 100 (e.g., one or more selected rows). The input signal may flow through the cross-point devices of the rows of the crossbar circuit 100. The conductance of the cross-point device may be tuned to a specific value (also referred to as a “weight”). By Ohm's law, the input voltage multiplies the cross-point conductance and generates a current from the cross-point device. By Kirchhoff's law, the summation of the current passing the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is outputted via each column wire and may be accumulated according to Kirchhoff's current law. This may enable in-memory computing (IMC) via parallel multiplications and summations performed in the crossbar arrays.

FIG. 2 is a schematic diagram illustrating an example 200 of a cross-point device in accordance with some embodiments of the present disclosure. As shown, cross-point device 200 may connect a bitline (BL) 211, a select line (SEL) 213, and a wordline (WL) 215. The bitline 211 and the wordline 215 may be a column wire and a row wire as described in connection with FIG. 1, respectively.

Cross-point device 200 may include an RRAM device 201 and a transistor 203. A transistor may include three terminals that are marked as gate (G), source (S), and drain (D), respectively. The transistor 203 may be serially connected to RRAM device 201. As shown in FIG. 2, the first electrode of the RRAM device 201 may be connected to the drain of transistor 203. The second electrode of the RRAM device 201 may be connected to the bitline 211. The source of the transistor 203 may be connected to the wordline 215. The gate of the transistor 203 may be connected to the select line 213. RRAM device 201 may be and/or include an RRAM device 303a-i, 440a, 440b, and/or 600a-e as described in connection with FIGS. 3A-6E below. Cross-point device 200 may also be referred to as a one-transistor-one-resistor (1T1R) configuration. The transistor 203 may perform as a selector as well as a current controller, which may set the current compliance, to the RRAM device 201 during programming. The gate voltage on transistor 203 can set current compliances to cross-point device 200 during programming and can thus control the conductance and analog behavior of cross-point device 200. For example, when cross-point device 200 is set from a high-resistance state to a low-resistance state, a set signal (e.g., a voltage signal, a current signal) may be provided via the bitline (BL) 211. Another voltage, also referred as a select voltage or gate voltage, may be applied via the select line (SEL) 213 to the transistor gate to open the gate and set the current compliance, while the wordline (WL) 215 may be set to ground. When cross-point device 200 is reset from the low-resistance state to the high-resistance state, a gate voltage may be applied to the gate of the transistor 203 via the select line 213 to open the transistor gate. Meanwhile, a reset signal may be sent to the RRAM device 201 via the wordline 215, while the bitline 211 may be set to ground. In some embodiments, the width of the bitline 211 and/or the wordline 215 may be about or greater than 1 μm.

FIG. 3A is a schematic diagram illustrating an example semiconductor device 300a with SoC integration of RRAM devices with varying characteristics in accordance with some embodiments of the present disclosure.

Semiconductor device 300a may further include a plurality of interconnect layers 350 fabricated on a substrate 310 (e.g., a substrate including silicon (Si), silicon dioxide (SiO₂), silicon nitride (Si₃N₄), aluminum oxide (Al₂O₃), aluminum nitride (AlN), etc.). Each of the interconnect layers 350 may provide electrical connectivity between devices fabricated on substrate 310. The interconnect layers 350 may include, for example, via layers V0, V1, V2, V3, V4, V5, . . . , and V6 and metal layers M1, M2, M3, M4, M5, M6, . . . , M7. While certain numbers of via layers and metal layers are shown in FIG. 3A for illustration simplification, additional via layers and metal layers may be fabricated for integration and/or interconnection needs. As shown, a pair of neighboring metal layers may be connected through a via layer fabricated between the neighboring metal layers. Each of the via layers may include one or more metallic vias. Each of the metallic vias may include a suitable metallic material, such as Al, Cu, W, etc. Each of the metal layers may include one or more metallic pads. Each of the metallic pads may include a suitable metallic material, such as Al, Cu, W, etc. In some embodiments, the via layer V0 may include tungsten (W) vias and doped polycrystalline Si (poly-Si) terminals where poly-Si terminals may connect transistor or diode terminals (not shown in FIG. 3A). The tungsten vias may directly contact the poli-Si terminals. The other via layers and metal layers above the via layer V0 may be fabricated with Cu, W, Al, etc. A metallic via or metallic pad of an interconnect layer is also referred to as “a metallic interconnect” herein.

The interconnect layers 350 may have varying dimensions. The sizes of the metallic pads of the metal layers M1, M2, . . . , M7, may increase sequentially. Similarly, the sizes of the metallic via in the via layers V0, V1, . . . , V6, may increase sequentially. For example, the semiconductor device 300a may be part of a 65 nm technology node. The width and the spacing of the metallic pads of the metal layer M1 may be about 90 nm. The width and the spacing of the metallic pads of the metal layers M5 and M6 may be about 100 nm. The width and the spacing of the metallic pads of the metal layers M7 may be about 400 nm.

As shown, semiconductor device 300a may include multiple RRAM devices 303a, 303b, . . . , 303i fabricated on a single complementary metal-oxide-semiconductor (CMOS) substrate 301. CMOS substrate 301 may include the substrate 310 and one or more interconnect layers (e.g., V0, M1, V1, etc.). In some embodiments, substrate 310 may include diodes, transistors, integrated circuits, etc. (not shown in FIG. 3A). Substrate 310 may include a driving circuit including one or more electrical circuits (e.g., an array of electrical circuits) that may be individually controllable. In some embodiments, the driving circuit may include one or more CMOS drivers.

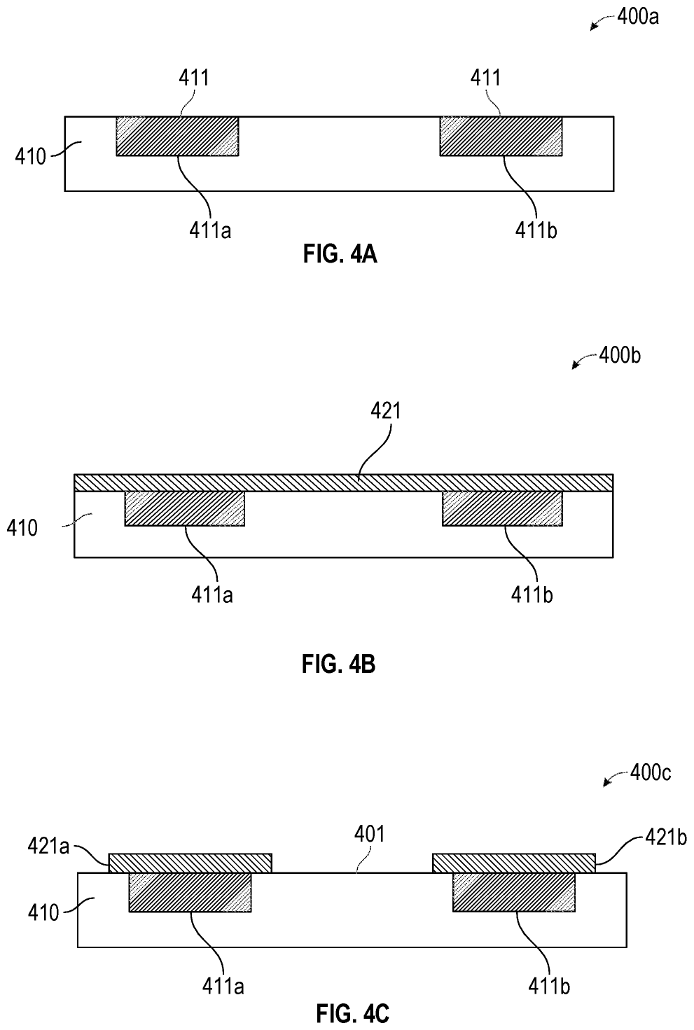

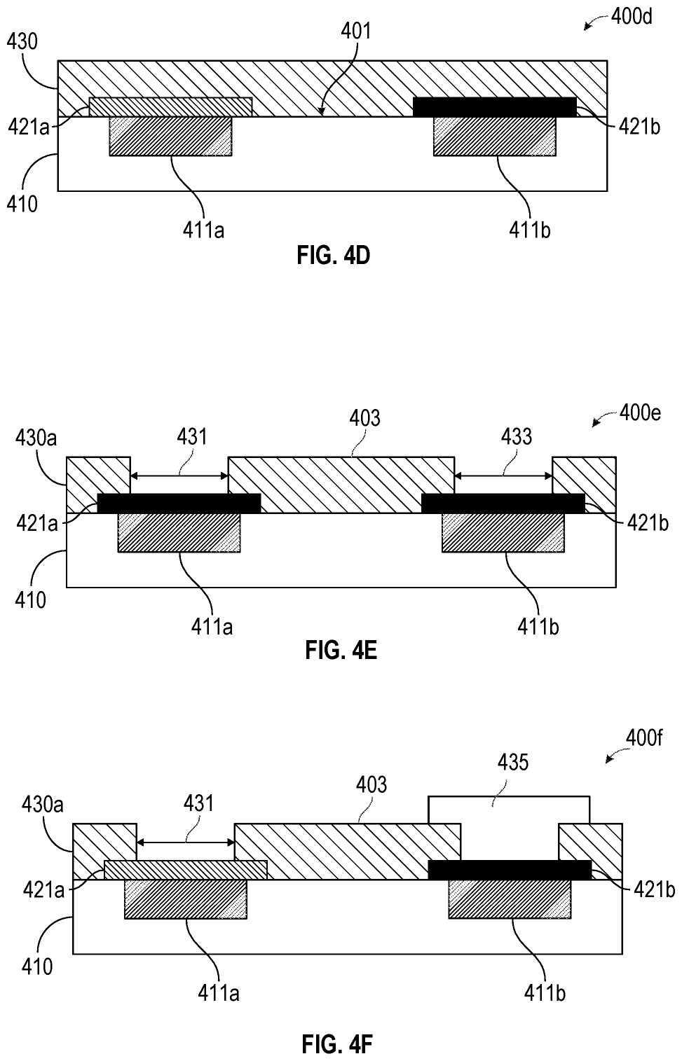

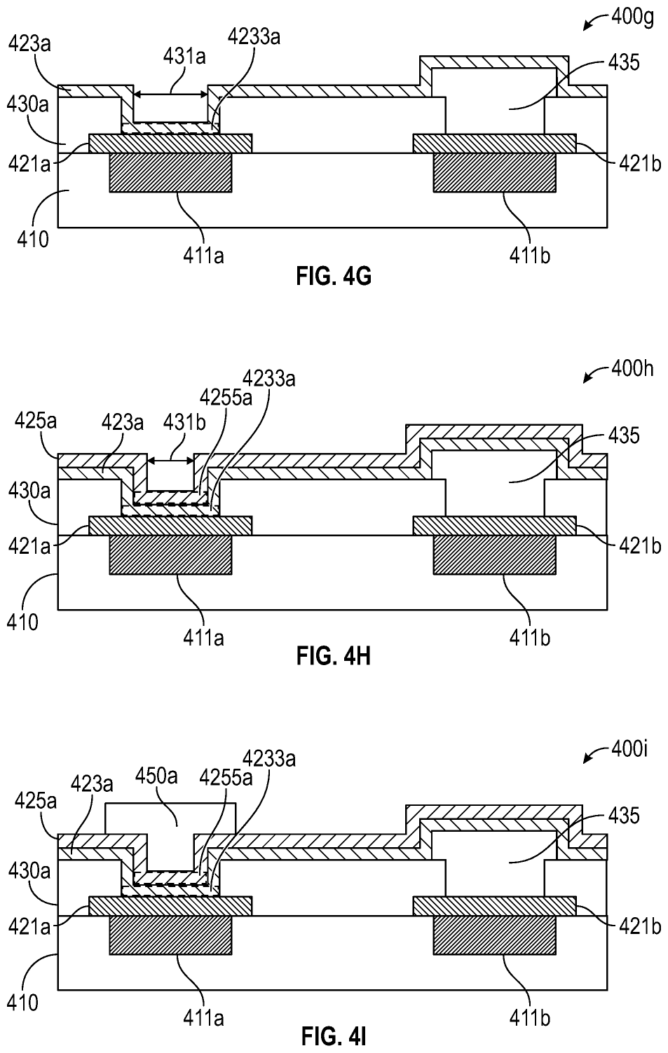

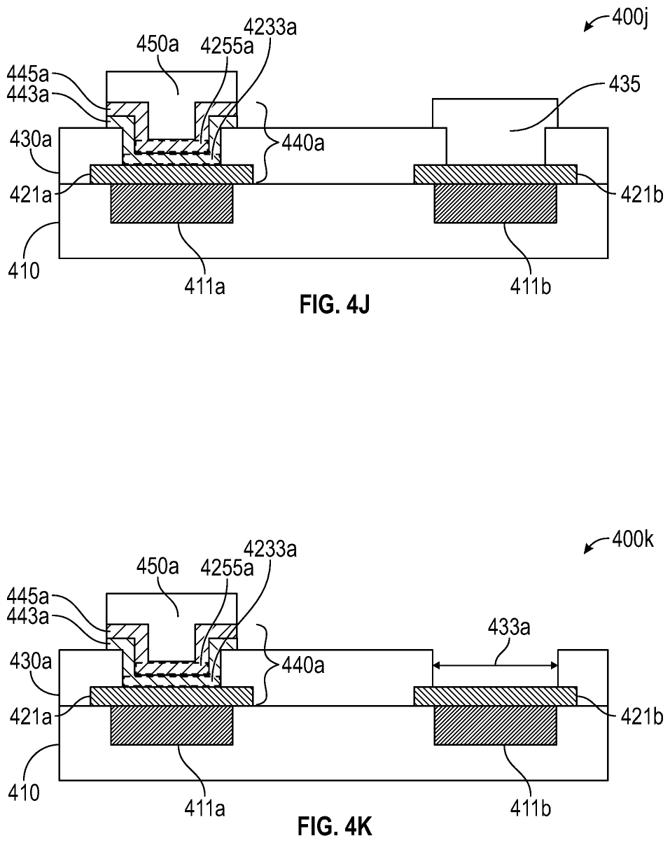

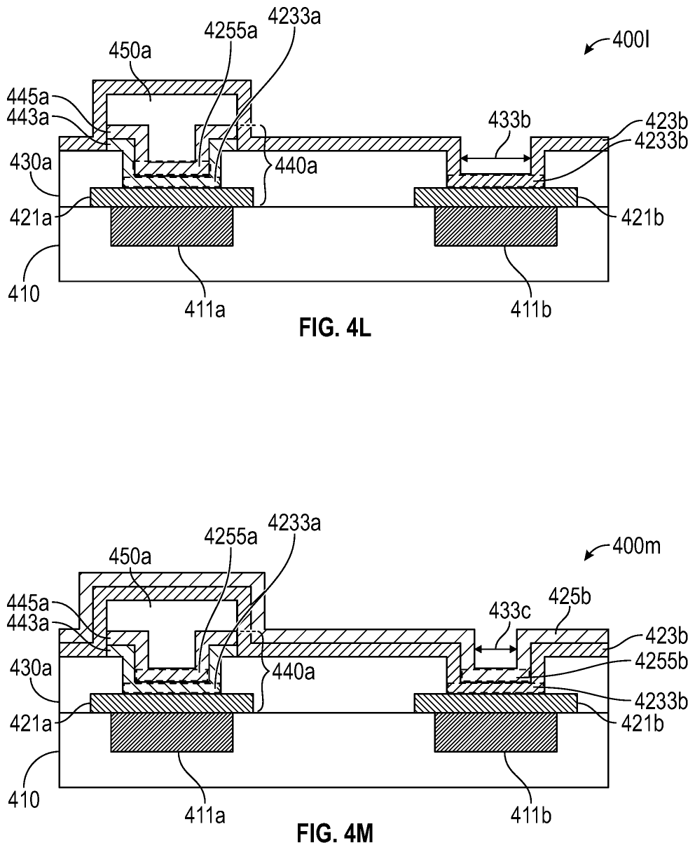

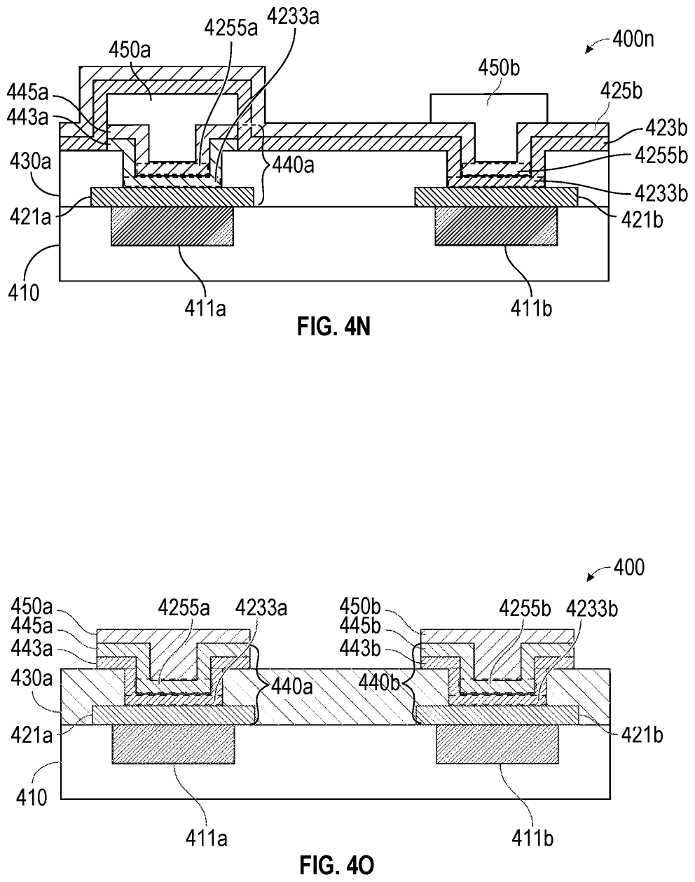

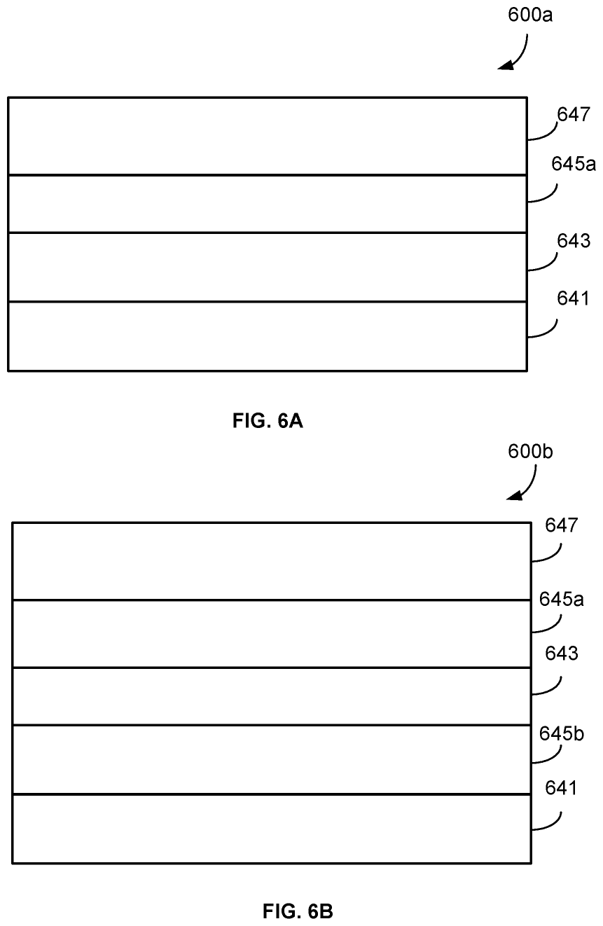

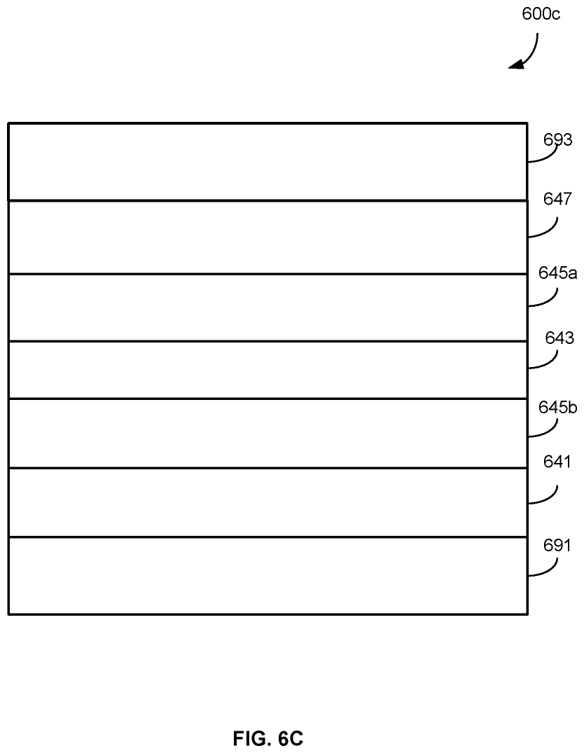

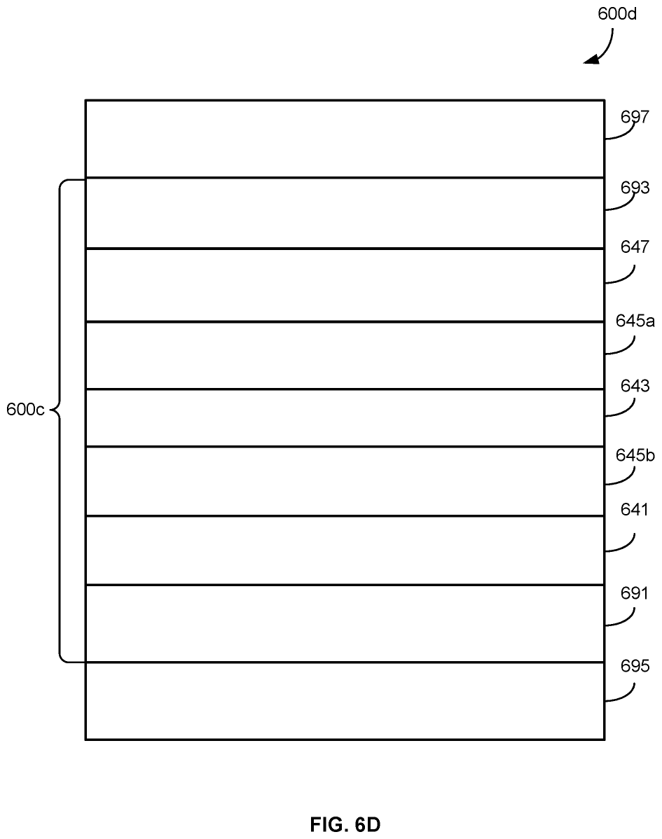

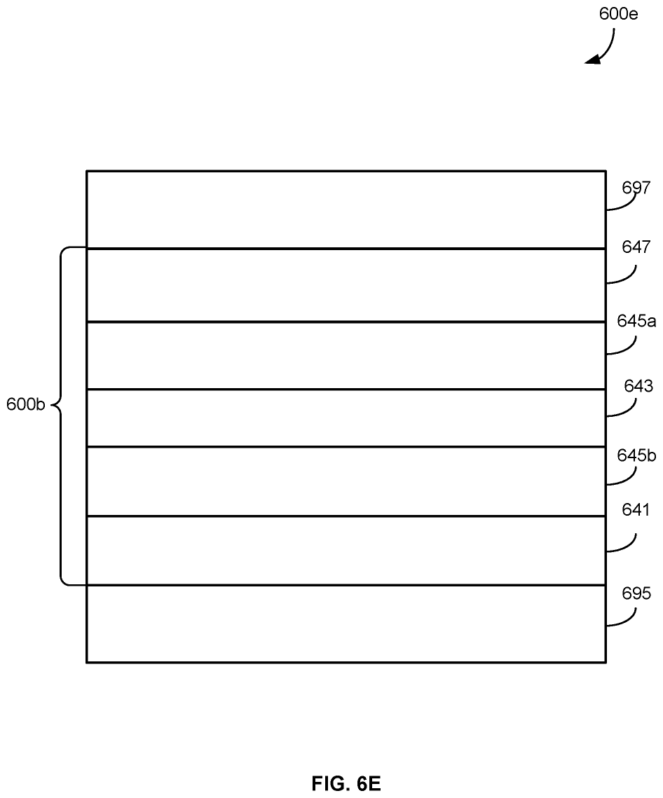

As shown, RRAM devices 303a, 303b, . . . , 303i may be fabricated on one or more interconnect layers 350. Two or more RRAM devices 303a, 303b, . . . , 303i may be fabricated on the same interconnect layer. For example, RRAM devices 303a and 303b may be fabricated on metal layer M4, while RRAM device 303i is fabricated on metal layer M6. Multiple RRAM devices in semiconductor device 300a may present various resistive switching behaviors suitable for implementing different crossbar circuit applications (e.g., memory, in-memory computing, storage applications, etc. In some embodiments, RRAM devices 303a, 303b, and 303i may include different device stacks for implementing the applications. Each of RRAM devices 303a, 303b, and 303i may include a device stack including a bottom electrode, a switching oxide layer, and a top electrode. Each of RRAM devices 303a, 303b, and 303i may include a device stack as described in connection with FIGS. 6A-6E. In some embodiments, RRAM devices 303a, 303b, and 303i may include different device stacks. For example, RRAM device 303a may include a bottom electrode including TiN, a switching oxide layer including HfOₓ, and a top electrode including Ta. As another example, RRAM device 303b may include a bottom electrode including Pt, a switching oxide layer including TaOx, and a top electrode including Ta. In some embodiments, RRAM devices 303a and 303b may include the same bottom electrode materials, such as Pt, TiN, etc. In some embodiments, RRAM devices 303a and/or 303b may further include an interface layer including Al₂O₃ fabricated between the switching oxide layer and the top electrode of the second RRAM device. RRAM device 303i may be a bipolar RRAM or a unipolar RRAM and may be fabricated on a different interconnect layer, as shown in FIG. 4A. In some embodiments, RRAM device 303i may be a unipolar RRAM device including a bottom electrode including Cu and/or CuO₂, a switching oxide layer including SiO₂, and a top electrode including Cu. The top electrode of RRAM device 303i (e.g., a top electrode of Cu) may be integrated into interconnect layers including Cu during a CMOS fabrication process in some embodiments.

In some embodiments, RRAM devices 303a, 303b, and 303i may be part of various crossbar arrays. For example, RRAM devices 303a, 303b, and 303i may be part of a first crossbar array, a second crossbar array, and a third crossbar array, respectively. Each of the first crossbar array, the second crossbar array, and the third crossbar array may be and/or include a crossbar circuit 100 as described in connection with FIG. 1. In some embodiments, two or more RRAM devices 303a, 303b, and 303i may be part of the same crossbar array. The first crossbar array, the second crossbar array, and the third crossbar array may be used to implement various applications (e.g., storage, memory, in-memory computing, etc.) in some embodiments. For example, the first crossbar array, the second crossbar array, and the third crossbar array may be used to implement a first application, a second application, and a third application, respectively. The second application and/or the third application may be different from the first application. RRAM devices 303a, 303b, and 303i may present varying switching behaviors for implementing the different applications. For example, RRAM devices 303a, 303b, and 303i may present bipolar switching behavior. As another example, RRAM devices 303a and 303b may present bipolar switching behavior, and RRAM device 303i may present unipolar switching behavior.

In one implementation, the bottom electrodes of RRAM devices 303a, 303b, and 303i may include a common material. In another example, the bottom electrodes of RRAM devices 303a, 303b, and 303i may include different materials.

FIGS. 3B, 3C, and 3D are schematic diagrams illustrating cross-sectional views of structures 300b, 300c, and 300d for fabricating the semiconductor device 300a of FIG. 3A in accordance with some embodiments of the present disclosure.

As shown in FIG. 3B, transistors 321, 323, and 325 may be fabricated on substrate 310. Transistor 321 may include a source region 321a, a gate region 321b, and a drain region 321c. Transistor 323 may include a source region 323a, a gate region 323b, and a drain region 323c. Transistor 325 may include a source region 325a, a gate region 325b, and a drain region 325c. While a certain number of transistors are shown in FIG. 3B, this is merely illustrative. Any suitable number of transistors may be fabricated on substrate 310.

As shown in FIG. 3C, one or more interconnect layers 350a (also referred to as the “first interconnect layers”) may be fabricated on the transistors. First interconnect layers 350a may be and/or include one or more metal layers and/or via layers as described in connection with FIG. 3A above.

As shown in FIG. 3C, a first via layer 341 may be fabricated on transistors 321, 323, and 325. First via layer 341 may include metallic vias 341a-341i. Metallic vias 341a, 341b, and 341c may be fabricated on source region 321a, gate region 321b, and drain region 321c of transistor 321, respectively. Metallic vias 341d, 341e, and 341f may be fabricated on source region 323a, gate region 323b, and drain region 323c of transistor 323, respectively. Metallic vias 341g, 341h, and 341i may be fabricated on source region 325a, gate region 325b, and drain region 325c of transistor 325, respectively.

A first metal layer 351 may be fabricated on first via layer 341. First metal layer 351 may include metallic pads 351a-351i that may be fabricated on metallic vias 341a-341i, respectively. In some embodiments, the metallic pads of first metal layer 351 may directly contact the metallic vias of first metallic via layer 341. Each of the interconnect layers 350a may be fabricated by fabricating a dielectric layer (e.g., dielectric layers 361 and/or 363), patterning the dielectric layer, and depositing suitable metals in the patterned dielectric layer.—

A plurality of RRAM devices may be fabricated on the top interconnect layer of first interconnect layers 350a. For example, RRAM devices 331 and 333 may be fabricated on metallic pads 351c and 351f, respectively. RRAM devices 331 and 333 may correspond to RRAM devices 303a and 303b of FIG. 3A, respectively. It is to be noted that RRAM devices 331 and 333 may be fabricated on any suitable interconnect layer as described herein. For example, one or more additional interconnect layers (not shown in FIG. 3C) may be fabricated between via layer 341 and metal layer 351 in some embodiments. As another example, RRAM devices 331 and 333 may be fabricated on via layer 341 in some embodiments.

As shown in FIG. 3D, one or more interconnect layers 350b (also referred to as the “second interconnect layers”) may be fabricated on RRAM devices 331 and 333. Interconnect layers 350a and 350b are also referred to as interconnect layers 350. Each of second interconnect layers 350b may be a metal layer and/or a via layer as described in connection with FIG. 3A. For example, second interconnect layers 350b may include via layers 343, . . . , 345, and metal layers 353, . . . , 355. The metallic pads 355a-355i of metal layer 355 may be connected to the metallic pads 353a-353i of metal layer 353 through the metallic vias 345a-345i of via layer 345, respectively. The metallic pads of metal layers 353 and 351 may be connected through the metallic vias 343a-343i of via layer 343. In some embodiments, a third RRAM device 335 may be fabricated on an interconnect layer (also referred to as the “third interconnect layer”) of the second interconnect layers 350b. For example, RRAM device 335 may be fabricated on metal layer 353 as shown in FIG. 3D. While a certain number of interconnect layers are shown in FIG. 3C, this is merely illustrative. Second interconnect layers 350b may include any suitable number of interconnect layers. Each of second interconnect layers 350b may be fabricated by fabricating a dielectric layer (e.g., dielectric layers 365, 367, 369, and 371), patterning the dielectric layer, and depositing suitable metals in the patterned dielectric layer. In some embodiments, a via layer and a metal layer (e.g., via layer 343 and metal layer 353) may be fabricated utilizing a dual-damascene fabrication process.

FIGS. 4A-4O are schematic diagrams illustrating cross-sectional views of example structures 400a, 400b, 400c, 400d, 400e, 400f, 400g, 400h, 400i, 400j, 400k, 400l, 400m, and 400n for fabricating an example 400 of a semiconductor device including RRAM devices for implementing varying crossbar circuit applications in accordance with some embodiments of the present disclosure.

As shown in FIG. 4A, a substrate 410 may be provided. Substrate 410 may include one or more layers of any suitable material that may serve as a substrate for fabricating an RRAM device, such as silicon (Si), silicon dioxide (SiO₂), silicon nitride (Si₃N₄), aluminum oxide (Al₂O₃), aluminum nitride (AlN), etc. In some embodiments, substrate 410 may include diodes, transistors, interconnects, integrated circuits, etc. Substrate 410 may include a driving circuit including one or more electrical circuits (e.g., an array of electrical circuits) that may be individually controllable. In some embodiments, the driving circuit may include one or more complementary metal-oxide-semiconductor (CMOS) drivers. In some embodiments, substrate 410 may include one or more dielectric layers, interconnect layers, transistors, and/or any other suitable component (not shown) for fabricating a crossbar circuit. In some embodiments, substrate 410 may be and/or include a CMOS substrate 301 as described in connection with FIG. 3A above.

As illustrated in FIG. 4A, substrate 410 may include a first interconnect layer including one or more metallic pads and/or metallic vias. For example, a first metal layer 411 may include metallic pads 411a and 411b. Metal pads 411a and 411b may include any suitable metal, such as Tungsten (W). Each of metallic pads 411a and 411b may be connected to a terminal of the transistors. For example, metallic pads 411a and 411b may be metallic pads 351c and 351f of FIG. 3C that are connected to drain region 321c of transistor 321 and drain region 323c of transistor 323, respectively. As another example, metallic pads 411a and 411b may be metallic vias 341c and 341f of FIG. 3A, respectively.

As shown in FIG. 4B, a bottom electrode layer 421 may be fabricated on metallic pads 411a and 411b, and substrate 410. Bottom electrode layer 421 may be and/or include a layer of a suitable material that is electronically conductive and nonreactive to the switching oxide of the RRAM devices to be fabricated on substrate 410. Examples of the nonreactive materials may include platinum (Pt), palladium (Pd), iridium (Ir), titanium nitride (TiN), tantalum nitride (TaN), etc.

Bottom electrode layer 421 may be patterned and etched to fabricate first bottom electrode 421a and second bottom electrode 421b. For example, as shown in FIG. 4C, bottom electrode layer 421 may be patterned and etched to form a first bottom electrode 421a and a second bottom electrode 421b on metallic pad 411a and metallic pad 411b, respectively. As shown, the lateral dimension of bottom electrode 421a-b may be greater than that of metallic pads 411a-b in some embodiments. First bottom electrode 421a may directly contact metallic pad 411a to form an ohmic contact. Second bottom electrode 421b may directly contact the second metallic pad 411b to form an ohmic contact. First bottom electrode 421a and second bottom electrode 421b may further contact one or more portions of substrate 410, such as one or more portions of a surface 401 of the substrate 410 (e.g., the top surface of the substrate 410). In some embodiments, bottom electrode layer 421 may include one or more metals that may enhance adhesion between first bottom electrode 421a and metallic pad 411a, adhesion of second bottom electrode 421b to second metallic pad 411b, and/or adhesion of first bottom electrode 421a and second bottom electrode 421b to substrate 410, such as tantalum (Ta), Titanium (Ti), etc.

In some embodiments, first bottom electrode 421a and second bottom electrode 421b may include different metallic materials and may be fabricated by depositing the metallic materials on metallic pads 411a and 411b, respectively.

As shown in FIG. 4D, a first etch stop layer 430 may be fabricated on substrate 410, first bottom electrode 421a, and second bottom electrode 421b. In some implementations, first etch stop layer 430 may directly contact the top surface 401 of substrate 410, first bottom electrode 421a, and second bottom electrode 421b. First etch stop layer 430 may include any suitable material that may be resistant to an etch process performed on a dielectric layer described herein (e.g., a layer of SiO₂). For example, first etch stop layer 430 may include one or more layers of silicon nitride (SiNₓ), silicon oxynitride (SiOₓN_{y}), etc.

As shown in FIG. 4E, one or more portions of first etch stop layer 430 may be selectively removed to expose a portion of each bottom electrode fabricated on substrate 410. For example, first etch stop layer 430 may be patterned and etched (e.g., utilizing suitable lithography techniques). The etching of first etch stop layer 430 may stop on first bottom electrode 421a and second bottom electrode 421b. The selective removal of the portion(s) of first etch stop layer 430 may expose one or more portions of first bottom electrode 421a and second bottom electrode 421b and may create vias 431 and 433 in the etched first etch stop layer 430 (also referred to as etch stop layer 430a). As shown, the via bottom of via 431 may directly contact the exposed portion of first bottom electrode 421a. Similarly, the via bottom of via 433 may directly contact the exposed portion of second bottom electrode 421b. In some embodiments, a dimension (e.g., a diameter) of vias 431 and/or 433 may be about or less than 1 μm. The lateral dimension of bottom electrodes 421a-b and the lateral dimension of metallic pads 411a-b may be greater than the dimension of vias 431 and/or 433.

Referring to FIG. 4F, a dielectric layer 435 may be deposited in via 433 and on one or more portions of the surface 403 of etch stop layer 430a. Dielectric layer 435 may include any suitable dielectric material, such as silicon dioxide (SiO₂), etc. Dielectric layer 435 may be fabricated by conformally depositing a layer of the dielectric material on the top surface 403 of etch stop layer 430a to fill via 433. The layer of the dielectric material may be patterned and etched to expose via 431. As such, dielectric layer 435 contacts second bottom electrode 421b and does not fill any portion of via 431 and does not contact first bottom electrode 421a. As shown in FIG. 4F, one or more portions of dielectric layer 435 are fabricated on the top surface 403 of etch stop layer 430a.

Referring to FIG. 4G, a first switching oxide layer 423a may be fabricated on dielectric layer 435 and etch stop layer 430a, and in via 431. First switching oxide layer 423a may include one or more switching oxides, such as TaOₓ, HfOₓ, TiOₓ, NbOₓ, ZrOₓ, SiOₓ, etc., in binary oxides, ternary oxides, and high order oxides, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and x≤2.5 for TaOₓ (where Ta₂O₅ being the full oxide). In some embodiments, first switching oxide layer 423a may include SiO₂. First switching oxide layer 423a may be conformally fabricated on the top surface of etch stop layer 430a, the exposed portions of first bottom electrode 421a, and dielectric layer 435, and along the sidewalls of via 431. In some embodiments, first switching oxide layer 423a may be fabricated over the top surface of dielectric layer 435 and along sidewalls of dielectric layer 435. As shown, portions 4233a of first switching oxide layer 423a are fabricated on the exposed portion of first bottom electrode 421a in via 431. The fabrication of first switching oxide layer 423a may create a via 431a that corresponds to the portions of via 431 that are not filled by first switching oxide layer 423a.

Referring to FIG. 4H, first top electrode layer 425a may be fabricated on first switching oxide layer 423a. First top electrode layer 425a may include any suitable metallic material that is electronically conductive and reactive to the transition metal oxide in first switching oxide layer 423a. For example, first top electrode layer 425a may include one or more of Ta, Hf, Ti, TiN, TaN, and the like. In some embodiment, the first top electrode may include multiple layers of metallic films and/or may include more than one metallic element. As illustrated in FIG. 4H, first top electrode layer 425a may include a portion 4255a that is fabricated on portion 4233a of first switching oxide layer 423a. The formation of first top electrode layer 425a may create a via 431b, which may correspond to the unfilled portions of via 431a. As such, first top electrode layer 425a may be conformally fabricated on the top surface of first switching oxide layer 423a.

Referring to FIG. 4I, a second etch stop layer 450a may be fabricated on first top electrode layer 425a. Second etch stop layer 450a may include any suitable material that may be resistant to an etch process performed on a dielectric layer as described herein. For example, second etch stop layer 450a may include one or more layers of SiNₓ, SiOₓN_{y}, etc. As shown in FIG. 4I, second etch stop layer 450a may be fabricated on the top surface of first top electrode layer 425a and in via 431b. Second etch stop layer 450a may fill via 431b and may extend beyond via 431b. In some embodiments, second etch stop layer 450a may be fabricated by depositing a layer of SiNₓ, SiOₓN_{y}, etc. on the top surface of first top electrode layer 425a, and patterning and etching the layer of SiNₓ, SiOₓN_{y}, etc. Second etch stop layer 450a does not cover the component of the second RRAM device 440b (as shown in FIG. 4O).

Referring to FIG. 4J, first top electrode layer 425a and first switching oxide layer 423a may be patterned and selectively etched to fabricate an RRAM device 440a (e.g., utilizing suitable lithography techniques). For example, first top electrode layer 425a may be patterned and etched to form a first top electrode 445a of RRAM device 440a. First switching oxide layer 423a may be patterned and etched to form a first filament-forming layer 443a of RRAM device 440a. The fabrication of first filament-forming layers 443a may expose one or more portions of etch stop layer 430a and may expose the top surface and sidewalls of dielectric layer 435. Second etch stop layer 450a may function as an etch mask and may protect the portion 4233a of the first switching oxide layer 423a and the portion 4255a of the first top electrode layer 425a during the etching of first top electrode layer 425a and/or the etching of first switching oxide layer 423a. As second bottom electrode 421b is covered by dielectric layer 435, second bottom electrode 421b is not etched during the etching of first top electrode layer 425a and/or the etching of first switching oxide layer 423a. Due to a high selectivity between dielectric layer 435 and etch stop layer 450a (e.g., a high ratio of etching rates between the dielectric material in dielectric layer 435 and the material in etch stop layer 450a) may effectively etch the dielectric layer 435 and prevent the etching of the etch stop layer 450a.

Referring to FIG. 4K, dielectric layer 435 may be removed (e.g., etched) to expose one or more portions of second bottom electrode 421b. The removal of dielectric layer 435 may create a via 433a. Via 433a may or may not be same as via 433. As RRAM device 440a is covered by etch stop layer 450a, it is not etched during the removal of dielectric layer 435.

Referring to FIG. 4L, a second switching oxide layer 423b may be fabricated on the etch stop layers 430a and 450a, and in via 433a. Second switching oxide layer 423b may include one or more switching oxides, such as TaOₓ, HfOₓ, TiOₓ, NbOₓ, ZrOₓ, SiOₓ, etc., in binary oxides, ternary oxides, and high order oxides, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and x≤2.5 for TaOₓ (where Ta₂O₅ being the full oxide). In some embodiments, first switching oxide layer 423a and second switching oxide layer 423b may include different materials. For example, first switching oxide layer 423a may include a first switching oxide layer. Second switching oxide layer 423b may include a second switching oxide that is different switching oxide and not included in first switching oxide layer 423a.

Second switching oxide layer 423b may be conformally fabricated on the top surfaces of etch stop layer 430a and etch stop layer 450a, and along the sidewalls of etch stop layer 450a and via 433a. As shown, a portion 4233b of second switching oxide layer 423b are fabricated on the exposed portion of second bottom electrode 421b in via 433a. The fabrication of second switching oxide layer 423b may create a via 433b that corresponds to the portions of via 433a that are not filled by second switching oxide layer 423b.

Referring to FIG. 4M, a second top electrode layer 425b may be fabricated on second switching oxide layer 423b. Second top electrode layer 425b may include any suitable metallic material that is electronically conductive and reactive to the transition metal oxide in second switching oxide layer 423b. For example, second top electrode layer 425b may include one or more of Ta, Hf, Ti, TiN, TaN, and the like. Second top electrode layer 425b and first top electrode layer 425a may or may not include the same material. As illustrated in FIG. 4M, second top electrode layer 425b may include a portion 4255b that is fabricated on the portion 4233b of second switching oxide layer 423b. The formation of second top electrode layer 425b may create a via 433c, which may correspond to the unfilled portions of via 433b. As such, second top electrode layer 425b may be conformally fabricated on the top surface of second switching oxide layer 423b.

Referring to FIG. 4N, an etch stop layer 450b may be fabricated on second top electrode layer 425b and in via 433c. Etch stop layer 450b may include any suitable material that may be resistant to an etch process performed on a dielectric layer as described herein. For example, etch stop layer 450b may include one or more layers of SiNₓ, SiOₓN_{y}, etc. As shown in FIG. 4N, etch stop layer 450b may fill via 433c and may extend beyond via 433c. In some embodiments, etch stop layer 450b may be fabricated by depositing a layer of SiNₓ, SiOₓN_{y}, etc. on the top surface of second top electrode layer 425b and patterning the layer of SiNₓ, SiOₓN_{y}, etc.

Referring to FIG. 4O, second top electrode layer 425b and second switching oxide layer 423b may be patterned and selectively etched to fabricate an RRAM device 440b (e.g., utilizing suitable lithography techniques). For example, second top electrode layer 425b may be patterned and etched to form a second top electrode 445b of second RRAM device 440b. Second switching oxide layer 423b may be patterned and etched to form a second filament-forming layer 443b of RRAM device 440b. Etch stop layer 450b may thus function as a mask during the fabrication of second filament-forming layer 443b and second top electrode 445b. The fabrication of second filament-forming layer 443b may expose one or more portions of etch stop layer 430a. Etch stop layer 450b may function as an etch mask and may protect the portion 4233b of second filament-forming layer 443b and the portion 4255b of second top electrode 445b during the etching of second top electrode layer 425b and/or the etching of second switching oxide layer 423b. As first RRAM device 440a is covered by etch stop layer 450a, it is not etched during the etching of second top electrode layer 425b and/or the etching of second switching oxide layer 423b.

As shown in FIG. 4O, semiconductor device 400 includes a first RRAM device 440a and a second RRAM device 440b fabricated on a single substrate 410. First RRAM device 440a may include a first bottom electrode 421a fabricated on a first metallic interconnect (e.g., a first metallic pad or metallic via) of a first interconnect layer 411, a first top electrode 445a, and a first filament-forming layer 443a fabricated between first bottom electrode 421a and first top electrode 445a. The first bottom electrode 421a and the second bottom electrode 421b include the same metallic materials in some embodiments. At least a portion of first filament-forming layer 443a (e.g., the portion 4433a) and at least a portion of first top electrode 445a (e.g., the portion 4455a) may be fabricated in a first via (e.g., via 431). Second RRAM device 440b may include a second bottom electrode 421b fabricated on a second metallic interconnect (e.g., a metallic pad or metallic via) of interconnect layer 411, a second top electrode 445b, and a second filament-forming layer 443b that is fabricated between second bottom electrode 421b and second top electrode 445b. At least a portion of second filament-forming layer 443b (e.g., the portion 4233b) and at least a portion of second top electrode 445b (e.g., the portion 4255b) may be fabricated in a second via (e.g., via 433). As described above, first bottom electrode 421a and second bottom electrode 421b may or may not include the same material. First top electrode 445a and second top electrode 445b may or may not include the same material.

A conductive filament may form in the portion 4233a of first filament-forming layer 443a (also referred to as the “first filament-forming region 4233a”) when a suitable programming signal (e.g., a set voltage, a reset voltage, etc.) is applied to first top electrode 445a and first bottom electrode 421a. Similarly, a conductive filament may form in the portion 4233b of second filament-forming layer 443b (also referred to as the “second filament-forming region 4233b”) when a suitable programming signal is applied to second top electrode 445b and second bottom electrode 421b. For example, each of RRAM devices 440a-b may have an initial resistance after it is fabricated. The initial resistance of RRAM device 440a-b may be changed, and RRAM device 440a-b may be switched to a state of a lower resistance via a forming process. During the forming process, a suitable voltage or current signal may be applied to RRAM device 440a-b. The application of the voltage or current signal to RRAM device 400a-b may induce the metallic material(s) in top electrode 445a-b to absorb oxygen from filament-forming regions 4233a-b and create oxygen vacancies in filament-forming regions 4233a-b. As a result, a conductive channel (e.g., a filament) which is oxygen vacancy rich may form in filament-forming regions 4233a-b. The portions of the filament-forming layers 445a-b that do not contact bottom electrodes 421a-b are not subject to an electric field during the forming process. Only the filament-forming regions 4233a-b contacting the bottom electric are between the top electrode and the bottom electrode and are subject to an electric field during the operation of the RRAM device 440a-b. The RRAM device 440a-b may be reset to a high-resistance state by applying a reset signal (e.g., a voltage signal or a current signal) to the RRAM device 440a-b. The application of the reset signal may cause oxygen to drift back to the filament-forming region 4233a-b of the filament-forming layer 443a-b and recombine with one or more of the oxygen vacancies. For example, an interrupted conductive channel (not shown) may be formed in the filament-forming region 4233a-b of the filament-forming layer 443a-b during the reset process. The conductive channel may be interrupted by an oxide gap with poor oxygen vacancies between the interrupted conductive channel and bottom electrode 421a-b. The portion of the filament-forming layer 443a-b that does not contact bottom electrode 421a-b is not subject to an electric field between top electrode 445a-b and bottom electrode 421a-b during the reset process. RRAM device 440a-b may be electrically switched between the high-resistance state and the low-resistance state by applying suitable programming signals (e.g., voltage signals, current signals, etc.) to RRAM device 440a-b.

First RRAM device 440a and second RRAM device 440b may include varying structures and/or materials and may present varying resistive switching behaviors. For example, first switching oxide layer 423a and second switching oxide layer 423b may include different materials. In some embodiments, second switching oxide layer 423b may include a switching oxide that is not included in first switching oxide layer 423a.

In some embodiments, first RRAM device 440a and second RRAM device 440b may be part of different crossbar circuits for implementing varying applications and/or circuit functions. For example, first top electrode 445a and second top electrode 445b may be connected to a first bitline (not shown) of a first crossbar circuit and a second bitline (not shown) of a second crossbar circuit, respectively. The first crossbar circuit and the second crossbar circuit may implement a first application (e.g., a memory or storage application) and a second application (e.g., an in-memory computing application), respectively. The first crossbar circuit and second crossbar circuit may be and/or include a crossbar circuit 100 of FIG. 1. Each of the first bitline and the second bitline may be a bitline 211 as described in connection with FIG. 1.

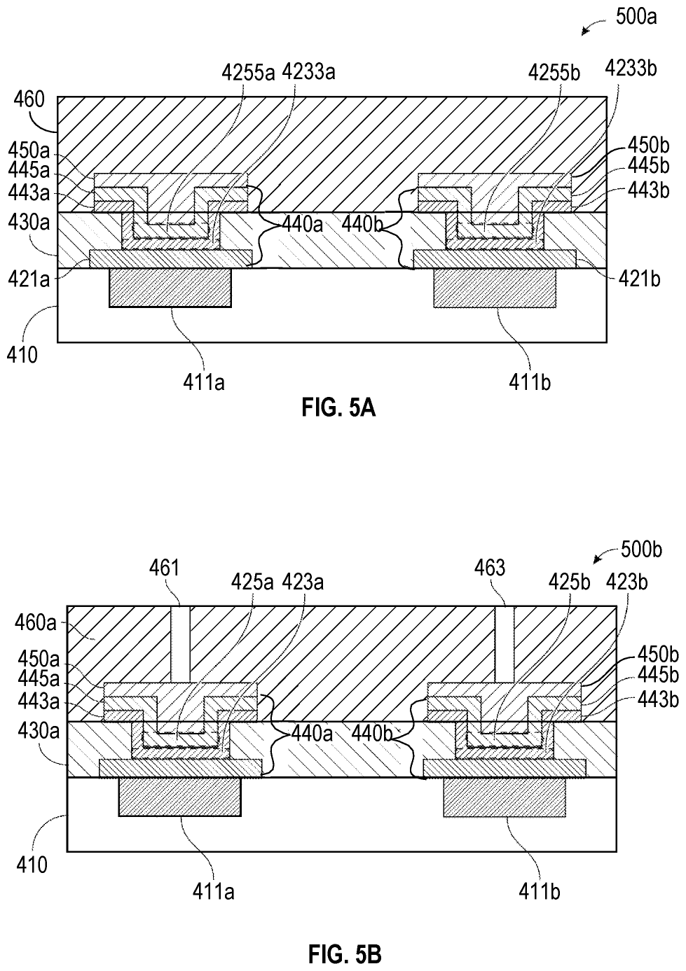

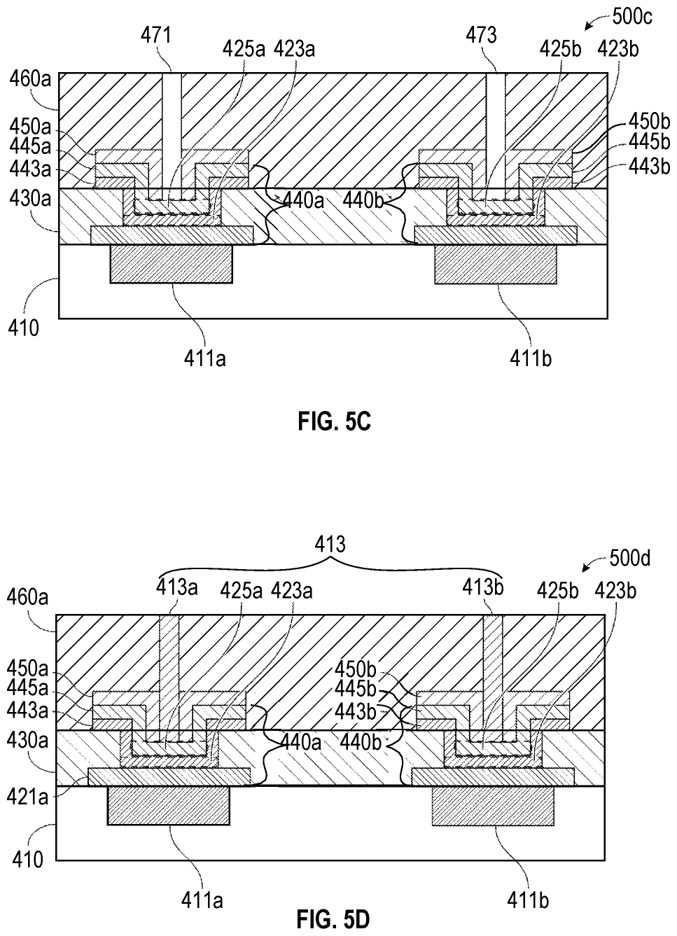

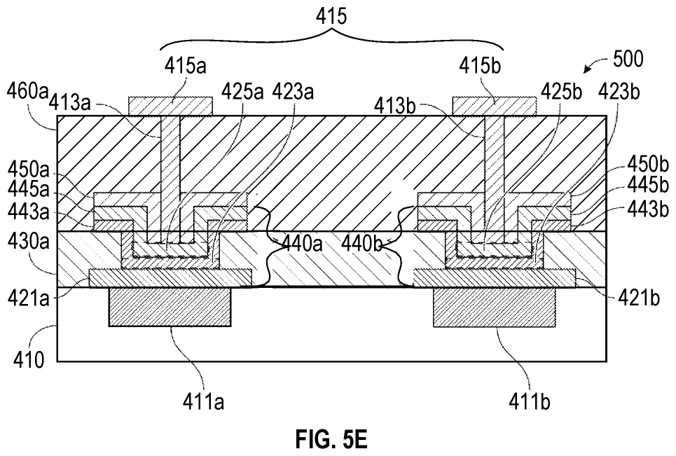

FIGS. 5A, 5B, 5C, 5D, and 5E illustrate cross-sectional views of structures 500a, 500b, 500c, 500d, and 500 relating to an example process for fabricating interconnect layers on the semiconductor device 400 of FIG. 4O in accordance with some embodiments of the present disclosure.

Referring to FIG. 5A, a dielectric layer 460 may be fabricated on etch stop layers 430a, 450a, and 450b. Dielectric layer 460 may include any suitable dielectric material, such as silicon dioxide (SiO₂), etc.

Referring to FIG. 5B, dielectric layer 460 may be selectively removed to fabricate via trenches 461 and 463. For example, dielectric layer 460 may be patterned and etched to form via trenches 461 and 463. As etch stop layers 450a-b and 430a are resistant to the etching of dielectric layer 460, the etching of dielectric layer 460 may stop on etch stop layers 450a-b. As such, etch stop layer 450a-b may enable highly selective etching of dielectric layer 460 and may protect first top electrode 445a and second top electrode 445b during the etching of dielectric layer 460. The etching of dielectric layer 460 may be regarded as stopping on an etch stop layer when the entire etch stop layer or a substantial portion of the etch stop layer is not etched during the etching of dielectric layer 460.

Referring to FIG. 5C, one or more portions of etch stop layers 450a-b are selectively removed to expand via trenches 461 and 463 and to create via trenches 471 and 473. The via bottom of via trenches 471 and 473 may contact first top electrode 445a (e.g., the portion 4255a of first top electrode 445a) and second top electrode 445b (e.g., the portion 4255b of second top electrode 445b), respectively. More particularly, for example, etch stop layer 450a may be patterned and etched to fabricate the bottom portion (the second portion) of via trench 471. Etch stop layer 450b may be patterned and etched to fabricate the bottom portion (the second portion) of via trench 473. The etching of etch stop layers 450a-b may stop on the top electrode 445a-b, respectively, due to a high selectivity between the etch of the etch stop layer and the metal.

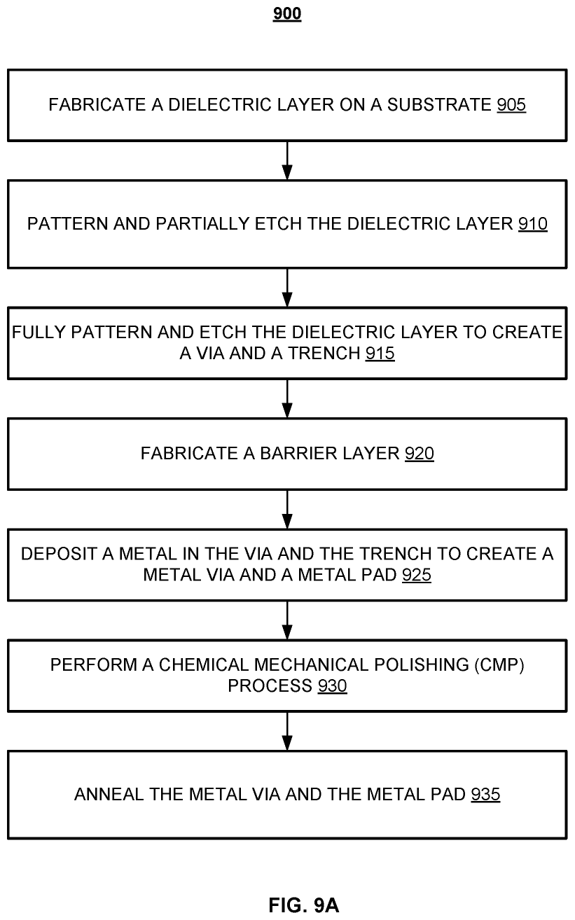

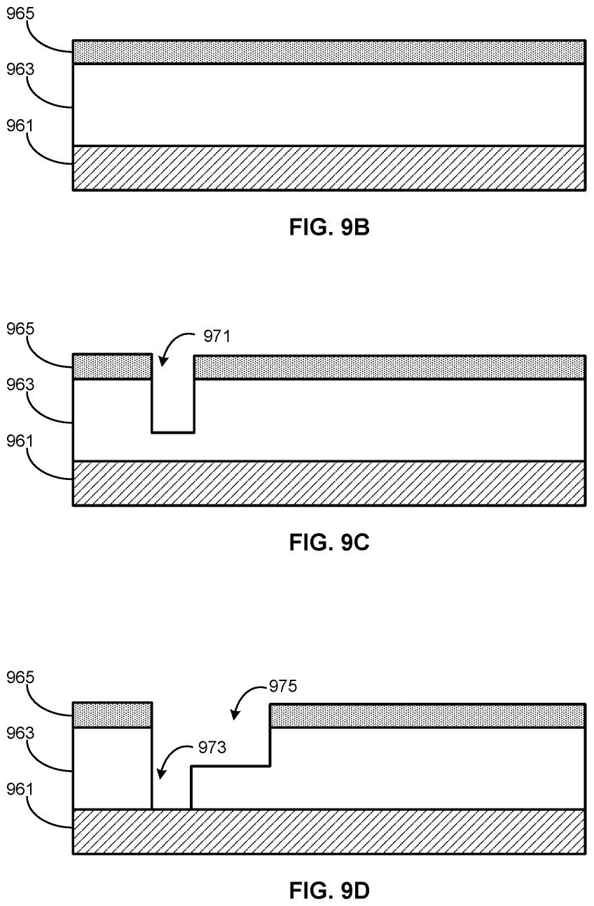

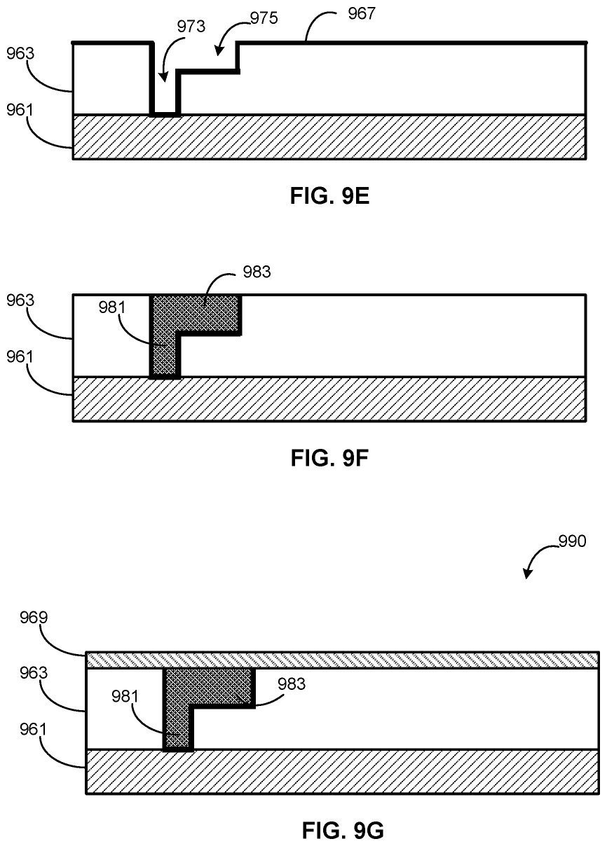

As shown FIG. 5D, metallic vias 413a and 413b of a second interconnect layer 413 may be fabricated by depositing suitable metals in via trenches 471 and 473. In some embodiments, as shown in FIG. 5E, a third interconnect layer 415 may be fabricated on second interconnect layer 413. Third interconnect layer may include metallic pads 415a and 415b, and may be fabricated on metallic vias 413a and 413b, respectively. In some embodiments, metallic vias 413a-b and metallic pads 415a-b may be fabricated utilizing a dual-damascene fabrication process (e.g., process 900 of FIG. 9A) in which metallic vias and metallic pads may be fabricated during the same metal deposition and patterning process.

Etch stop layer 450a-b may protect the top electrodes of RRAM devices 440a-b during the etching of the layers disposed on the RRAM devices. Etch stop layers 430 and 450a-b may enable high etching selectivity during the fabrication of RRAM devices 440a-b. The etch stop layers may function as etching masks in some of the etching processes described herein and may improve the process control and thus reduce manufacturing costs. Etch stop layers 430 and 450a-b may also function as a barrier or a spacer to isolate the oxygen diffusion from the dielectric materials to the RRAM devices for better device uniformity and device operation control. The mechanisms for fabricating the crossbar circuit as described herein may enable the fabrication of RRAM devices without using spacers during the etching processes.

FIGS. 6A, 6B, 6C, 6D, and 6E are schematic diagrams illustrating cross-sectional views of example RRAM devices 600a, 600b, 600c, 600d, and 600e in accordance with some embodiments of the present disclosure.

As shown in FIG. 6A, RRAM device 600a may include a bottom electrode 641, a switching oxide layer 643, an interface layer 645a, and a top electrode 647. The interface layer 645a (also referred to as the “interface layer A” or the “first interface layer”) is fabricated between the top electrode 647 and the switching oxide layer 643.

The switching oxide layer 643 may include one or more transition metal oxides, such as TaOₓ, HfOₓ, TiOₓ, NbOₓ, ZrOₓ, etc., in binary oxides, ternary oxides, and high order oxides, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and x≤2.5 for TaOₓ (where Ta₂O₅ being the full oxide). As an example, the switching oxide layer 643 may include Ta₂O₅. As the other example, the switching oxide layer 643 may include HfO₂.

The interface layer 645a may be and/or include a film of a first material that is more chemically stable than the transition metal oxide(s) in the switching oxide layer 643. As a result, the first material may not react with the transition metal oxide(s) of the switching oxide layer 643. As an example, the transition metal oxide(s) of the switching oxide layer may be and/or include one or more transition metal oxides, such as at least one of HfOₓ or TaO_{y}, wherein x≤2.0, and wherein y≤2.5, and the first material may include Al₂O₃, MgO, Y₂O₃, La₂O₃, etc.

The interface layer 645a may prevent excessive reactions between RRAM switching oxide and the top electrodes caused by additional thermal exposure to the RRAM device during the subsequent fabrication of interconnect layers on the RRAM device.

The interface layer 645a may have a suitable thickness to achieve desirable forming gas anneal (FGA) resistance. For example, a relatively thicker interface layer may be more FGA resistant than a relatively thinner interface layer. In one implementation, the interface layer 645a may include a discontinuous film of Al₂O₃, SiO₂, Y₂O₃, etc. In another implementation, the interface layer 645a may include a continuous film of Al₂O₃, SiO₂, Y₂O₃, La₂O₃, etc.

In some embodiments, as illustrated in FIG. 6B, an RRAM device 600b may include multiple interface layers. For example, an interface layer 645b (also referred to as the “interface layer B” or the “second interface layer”) may be fabricated between the bottom electrode 641 and the switching oxide layer 643. The interface layer 645b may be and/or include a film of a second material that is more chemically stable than the transition metal oxide(s) in the switching oxide layer 643. As a result, the second material may not react with the transition metal oxide(s) of the switching oxide layer 643. As an example, the transition metal oxide(s) of the switching oxide layer may be and/or include one or more transition metal oxides, such as at least one of HfOₓ or TaO_{y}, wherein x≤2.0, and wherein y≤2.5, and the second material may include Al₂O₃, MgO, Y₂O₃, La₂O₃, etc. The first material in the interface layer 645a may or may not be the same as the second material in the interface layer 645b. The interface layer 645a and/or 645b may also be useful where metal nitride being used as one of the bottom electrode or the top electrode.

The interface layer 645b may have a desired thickness to achieve desirable FGA resistance. For example, a relatively thicker interface layer may be more FGA resistant than a relatively thinner interface layer. In one implementation, the interface layer 645b may include a discontinuous film of Al₂O₃, SiO₂, Y₂O₃, etc. In another implementation, the interface layer 645b may include a continuous film of Al₂O₃, SiO₂, Y₂O₃, etc.

As shown in FIG. 6C, the RRAM device 600c may include a first diffusion barrier 691, a bottom electrode 641, an interface layer 645b, a switching oxide layer 643, an interface layer 645a, a top electrode 647, and a second diffusion barrier 693. The bottom electrode 641, the interface layer 645b, the switching oxide layer 643, the interface layer 645a, and the top electrode 647 may be the same as their counterparts as described in connection with FIGS. 6A-6B above. The first diffusion barrier 691 may be fabricated between the first interconnect layer 411 of FIGS. 4A-5E (not shown in FIG. 6C) and the bottom electrode 641. The second diffusion barrier 693 may be fabricated between the top electrode 647 and the second interconnect layer 413 of FIGS. 4A-5E (not shown in FIG. 6C).

The first diffusion barrier 691 and the second diffusion barrier 693 may include any suitable material that may prevent metals in the interconnect layers from diffusing into the RRAM device at annealing temperatures and may exhibit suitable thermal and chemical stability, conductivity, and adhesion. In some embodiments, the first diffusion barrier 691 and/or the second diffusion barrier 693 may include one or more layers of TaN, TiN, etc.

The first diffusion barrier 691 and/or the second diffusion barrier 693 may further enhance the annealing resistance of the RRAM device and prevent metals in the interconnects (e.g., Cu, Al, W) from diffusing into the RRAM device.

In some embodiments, one or more adhesion layers may be fabricated between the RRAM device 600c and the interconnect layers. For example, as shown in FIG. 6D, the RRAM device 600c may be fabricated on a first adhesion layer 695. The first adhesion layer 695 may be fabricated on the top interconnect layer of the first interconnect layers 350a of FIG. 3C (not shown in FIG. 6D).

A second adhesion layer 697 may be fabricated on the RRAM device 600c and/or the second diffusion barrier 693. One or more second interconnect layers 350b of FIGS. 3A-3D (not shown in FIG. 6D) may be fabricated on the second adhesion layer 697. Each of the first adhesion layer 695 and the second adhesion layer 697 may include one or more layers of Ti, Ta, or conductive oxide such as Ti₄O₇, etc.

In some embodiments, the first diffusion barrier 691 and/or the second diffusion barrier 693 may be omitted from RRAM device 600d. For example, as shown in FIG. 6E, RRAM device 600e may include the RRAM device 600b fabricated on the first adhesion layer 695. The second adhesion layer 697 may be fabricated on the top electrode 647.

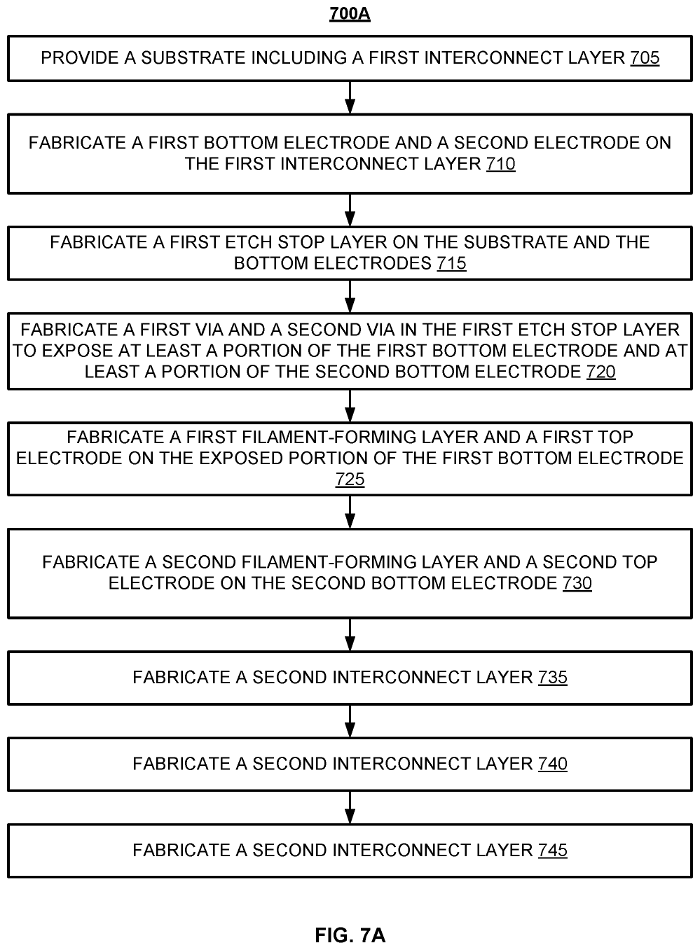

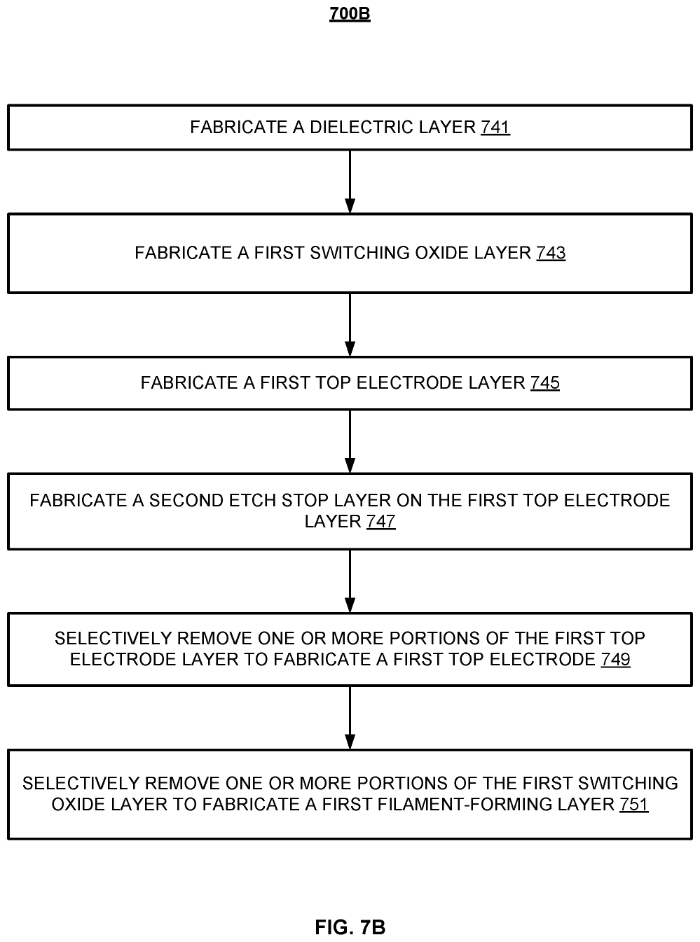

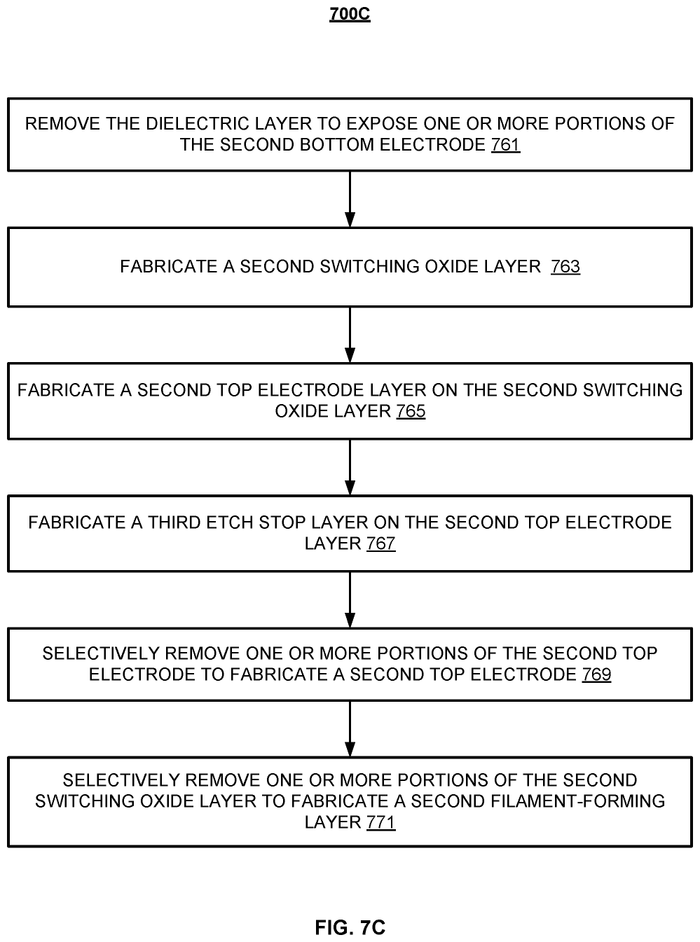

FIG. 7A is a flowchart illustrating an example process 700A for fabricating RRAM devices in accordance with some embodiments of the present disclosure. FIG. 7B is a flowchart illustrating an example process 700B for fabricating a first filament-forming layer and a first top electrode of a first RRAM device of the RRAM devices in accordance with some embodiments of the present disclosure. FIG. 7C is a flowchart illustrating an example process 700C for fabricating a second filament-forming layer and a second top electrode of a second RRAM device of the RRAM devices in accordance with some embodiments of the present disclosure.

Referring to FIG. 7A, process 700A may start at 705 where a substrate including a first interconnect layer is provided. The first interconnect layer may include one or more metallic pads and/or metallic vias for connecting the bottom electrodes and one/or more other components of the semiconductor device. The substrate may be the substrate 410 of FIG. 4A and/or the substrate 301 of FIG. 3A.

At block 710, a plurality of bottom electrodes may be fabricated on the first interconnect layer. For example, a first bottom electrode of a first RRAM device and a second bottom electrode of a second RRAM device may be fabricated on a first metallic interconnect and a second metallic interconnect of the first interconnect layer, respectively. In some implementations, the first metallic interconnect and the second metallic interconnect may be a first metallic pad and a second metallic pad of the first interconnect layer, respectively. In some implementations, the first metallic interconnect and the second metallic interconnect may be a first metallic via and a second metallic via of the first interconnect layer, respectively. The first metallic pad may be connected to a first transistor or a first diode. The second metallic pad may be connected to a second transistor or a second diode. The bottom electrodes may include bottom electrodes 421a and 421b and may be fabricated as described in connection with FIGS. 4B-4C.

In some embodiments, fabricating the one or more bottom electrodes may involve depositing, on the first interconnect layer and the substrate, a bottom electrode layer of one or more nonactive metals, such as Pt, Pd, Ir, etc. utilizing a physical vapor deposition (PVD) technique, a chemical vapor deposition (CVD) technique, a sputtering deposition technique, an atomic layer deposition (ALD) technique, and/or any other suitable deposition technique. In some embodiments, fabricating the bottom electrode layer may involve depositing one or more layers of Pt. The bottom electrode layer may then be patterned and etched to fabricate the bottom electrodes. In some embodiments, fabricating the bottom electrode layer may include depositing a metal nitride on a metallic pad or metallic via of the first interconnect layer. The metal nitride may include, for example, tantalum nitride, titanium nitride, etc.

At block 715, a first etch stop layer may be fabricated on the substrate and the bottom electrodes. Fabricating the first etch stop layer may involve depositing one or more materials that are resistant to the etching of a dielectric layer (e.g., a SiO₂ layer) to be fabricated on the first etch stop layer. For example, fabricating the first etch stop layer may involve depositing one or more layers of SiNₓ, SiOₓN_{y}, etc. utilizing CVD techniques, ALD techniques, magnetron sputtering techniques, etc. The first etch stop layer may be deposited on the bottom electrodes and the portions of the substrate that are not covered by the bottom electrodes. The first etch stop layer may be etch stop layer 430 as described in connection with FIGS. 4D.

At bock 720, one or more vias may be fabricated in the first etch stop layer to expose at least a portion of each of the bottom electrodes. For example, the first etch stop layer may be patterned and etched to create a first via in the first etch stop layer to expose a portion of the first bottom electrode and/or to create a second via in the first etch stop layer to expose a portion of the second bottom electrode. The via bottom of the first via and the via bottom of the second via may directly contact the first bottom electrode and the second bottom electrode, respectively. The vias may include vias 431 and 433 as described in connection with FIG. 4E.

At block 725, a first filament-forming layer and a first top electrode may be fabricated on the exposed portion of the first bottom electrode. The first filament-forming layer and the first top electrode may be first filament-forming layer 443a and first top electrode 445a as described in connection with FIG. 4O above. In some embodiments the first filament-forming layer and the first top electrode may be fabricated by performing one or more operations depicted in FIG. 7B.

Referring to FIG. 7B, at block 741, a dielectric layer may be fabricated in the second via and on the exposed portion of the second bottom electrode. Fabricating the dielectric layer may involve depositing one or more suitable materials that may be used as an interlayer dielectric (ILD) (e.g., SiO₂) on the top surface of the first etch stop layer and in the second via. The second isolation layer may fill the second via and may contact one or more portions of the top surface of the first etch stop layer. The dielectric layer may be dielectric layer 435 of FIG. 4F and may be fabricated as described in connection with FIG. 4F above.

At block 743, a first switching oxide layer may be fabricated. In some embodiments, fabricating the first switching oxide layer may involve depositing one or more switching oxides, such as TaOₓ, HfOₓ, TiOₓ, NbOₓ, ZrOₓ, SiO₂, etc. The first switching oxide layer may be deposited utilizing an atomic layer deposition (ALD) technique, physical vapor deposition (PVD) technique, chemical vapor deposition (CVD) technique, and/or any other suitable deposition technique. In some embodiments, the first switching oxide layer may be fabricated utilizing bottom anti-reflective coatings (BARC) and/or deep UV (DUV) lithography techniques.

The first switching oxide layer may be conformally fabricated on the portion of the first etch stop layer that surrounds the vias, along the sidewalls of the first via, and on the exposed portion of the first bottom electrode. The fabrication of the first switching oxide layer may partially fill the first via. The switching oxide layer may be fabricated as described in connection with FIG. 4G above.

At block 745, a first top electrode layer may be fabricated. In some embodiments, fabricating the first top electrode layer may involve depositing one or more suitable metallic materials that are electrically conductive and reactive to the switching oxide in the switching oxide layer, such as Ta, Hf, Ti, TiN, TaN, etc. The first top electrode layer may be fabricated on the first switching oxide layer, along the sidewalls of the first via, and along the sidewalls of the dielectric layer. The first top electrode layer may be first top electrode layer 425a as described in connection with FIG. 4H above. In some embodiments, the first top electrode layer may be fabricated utilizing in situ pre-sputtering etching techniques.

At block 747, a second etch stop layer may be fabricated on the first top electrode layer. Fabricating the second etch stop layer may involve depositing one or more materials that are resistant to the etching of a dielectric layer to be fabricated on the first top electrode layer. For example, fabricating the second etch stop layer may involve depositing one or more layers of SiNₓ, SiOₓN_{y}, etc. utilizing CVD techniques, ALD techniques, magnetron sputtering techniques, etc. The fabrication of the second etch stop layer may completely fill the first via in some embodiments. The second etch stop layer may be etch stop layer 450a as described in connection with FIG. 4I above.

At block 749, one or more portions of the first top electrode layer may be removed to fabricate the first top electrode. For example, the first top electrode layer may be etched to remove the portions of the first top electrode layer surrounding the second etch stop layer. The second etch stop layer may function as an etching mask during the etching of the first top electrode layer. At block 751, one or more portions of the first switching oxide layer may be selectively removed to fabricate the first filament-forming layer. Blocks 749 and 751 may be performed sequentially, simultaneously, substantially simultaneously, and/or in any other suitable order. In some embodiments, the first top electrode and/or the first switching oxide layer may be patterned and etched as described in connection with FIG. 4J above.

Referring back to FIG. 7A, at block 730, a second filament-forming layer and a second top electrode may be fabricated on the second bottom electrode. At least a portion of the second filament-forming layer is fabricated on the exposed portion of the second bottom electrode. The second filament-forming layer and the second top electrode may be second filament-forming layer 443b and second top electrode 445b of FIG. 4O, respectively. In some embodiments, fabricating the second filament-forming layer and the second top electrode may involve performing one or more operations depicted in FIG. 7C.

Referring to FIG. 7C, the dielectric layer fabricated at 741 may be removed (e.g., etched) to expose one or more portions of the second bottom electrode at block 761. The removal of the dielectric layer may create a via in the first etch stop layer (e.g., via 433a of FIG. 4K).

At block 763, a second switching oxide layer may be fabricated on the top surface of the first etch stop layer, the top surface of the second etch stop layer, and the exposed portion of the second bottom electrode. The second switching oxide layer may further be fabricated along the sidewalls in the second etch stop layer. The second switching oxide layer may be second switching oxide layer 423b of FIG. 4L. Fabricating the second switching oxide layer may include depositing one or more second switching oxides that are not included in the first switching oxide layer and/or the first filament-forming layer. The second switching oxide may include, for example, TaOₓ, HfOₓ, TiOₓ, NbOₓ, ZrOₓ, SiO₂, etc. The second switching oxide layer may be deposited utilizing ALD, PVD, CVD, and/or any other suitable deposition technique. In some embodiments, the second switching oxide layer may be fabricated utilizing bottom anti-reflective coatings (BARC) and/or deep UV (DUV) lithography techniques.

At block 765, a second top electrode may be fabricated on the second filament-forming layer. The second top electrode may be second top electrode 445b of FIG. 4M.

At block 767, a third etch stop layer may be fabricated on the second top electrode layer and in the second via. The third etch stop layer may be, for example, etch stop layer 450b of FIGS. 4N-4O. The third etch stop layer may fill the second via. One or more portions of the third etch stop layer contact the top surface of the second top electrode layer.

At block 769, the second top electrode of a second RRAM device may be fabricated by selectively removing one or more portions of the second top electrode layer. For example, the second top electrode layer may be etched to remove the portions of the second top electrode layer surrounding the third etch stop layer. The third etch stop layer may function as an etching mask during the etching of the second top electrode layer.

At block 771, the second switching oxide layer may be fabricated by selectively removing one or more portions of the second switching oxide layer. Blocks 769 and 771 may be performed sequentially, simultaneously, substantially simultaneously, and/or in any other suitable order. In some embodiments, the second top electrode and/or the second switching oxide layer may be patterned and etched as described in connection with FIG. 4O above.

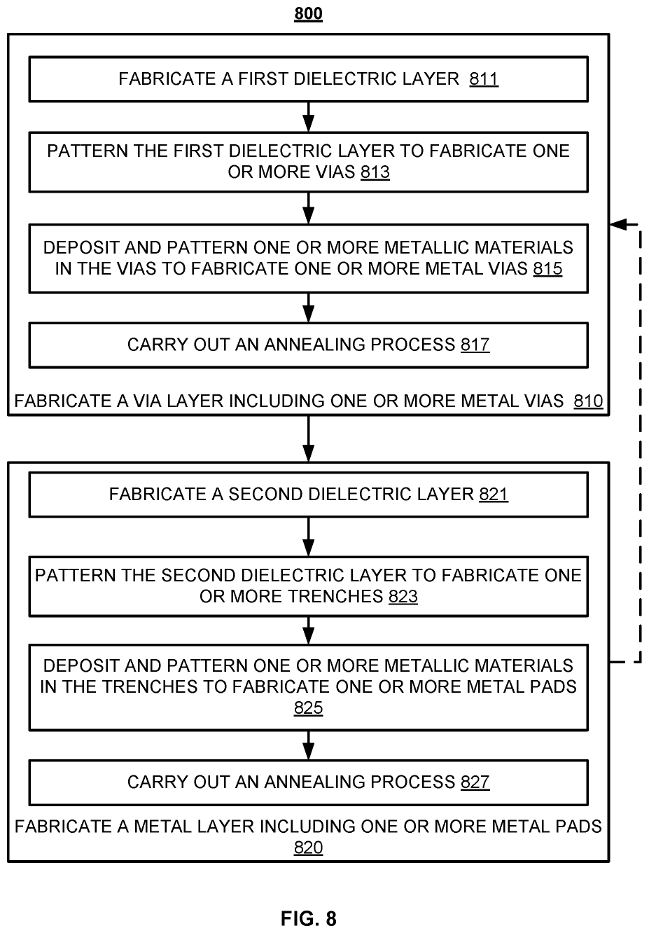

Referring back to FIG. 7A, a second interconnect layer may be fabricated at block 735. The second interconnect layer may include a plurality of metallic pads and/or metallic vias. For example, the second interconnect layer may include a first metallic via fabricated in a dielectric layer and the second etch stop layer. As another example, the second interconnect layer may include a second metallic via that is fabricated in the dielectric layer and the third etch stop layer. In some embodiments, fabricating the second interconnect layer may include fabricating metallic vias 413a-b and/or metallic pads 415a-b as described in connection with FIGS. 5A-5E above. In some embodiments, the second interconnect layer may be fabricated by performing one or more operations as described in connection with FIGS. 8-9G below.

In some embodiments, a third RRAM device may be fabricated at block 740. The third RRAM device, the first RRAM device, and the second RRAM device may be fabricated on different interconnect layers. The third RRAM device may be RRAM device 303i and/or RRAM device 335 as described in connection with FIGS. 3A-3D above. The third RRAM device may be fabricated on a third interconnect layer that is different from the first interconnect layer. The third interconnect layer may include one or more metallic vias or metallic pads. The third RRAM device, the first RRAM device may or may not include the same device stack. In some embodiments, the third RRAM device may be a unipolar RRAM device. The third RRAM device may be connected to a diode in some embodiments.

FIG. 8 is a flowchart illustrating an example process 800 for fabricating one or more interconnect layers in accordance with some embodiments of the present disclosure.

At 810, a via layer including one or more metallic vias may be fabricated. To fabricate the via layer, a first dielectric layer of a first dielectric material may be fabricated at 811. For example, a layer of the first dielectric material (e.g., Si₃N_{4,} Si₂O, etc.) may be deposited using suitable deposition techniques, such as chemical vapor deposition (CVD), atomic layer deposition (ALD), plasma-enhanced chemical vapor deposition (PECVD), sputtering, etc.

At 813, the first dielectric layer may be patterned to create one or more vias. The first dielectric layer may be patterned using any suitable dry and wet etching techniques.

At 815, one or more suitable metallic materials may be deposited in the vias and patterned to fabricate one or more metallic vias. For example, the first vias may be filled by depositing Cu, Al, W, and/or any other suitable metal utilizing CVD, PVD, and/or any other suitable deposition technique.

At 817, an annealing process is carried out. For example, the first via layer may be annealed in forming gas ambient at suitable temperatures (e.g., 350-450° C.) for a suitable period of time (e.g., 15-30 minutes). The forming gas may include a mixture of nitrogen (N₂) and hydrogen (H₂) in a suitable ratio (e.g., 95:5, 90:10, etc.).

At 820, a metal layer including one or more metallic pads may be fabricated on the via layer. To fabricate the metal layer, a second dielectric layer of a second dielectric material may be fabricated at 821. For example, a layer of the second dielectric material (e.g., SiO₂, Si₃N₄) may be deposited on the via layer using suitable deposition techniques, such as chemical vapor deposition (CVD), ALD, sputtering, etc.

At 823, the second dielectric layer may be patterned to create one or more trenches. The second dielectric layer may be patterned using any suitable dry and wet etching techniques.

At 825, one or more suitable metallic materials may be deposited in the trenches and patterned to fabricate one or more metallic pads. For example, the second vias may be filled by depositing Cu, Al, W, and/or any other suitable metal utilizing CVD, PVD, and/or any other suitable deposition technique.

At 827, an annealing process is carried out. For example, the metal layer may be annealed in forming gas ambient at suitable temperatures (e.g., 350-450° C.) for a suitable period of time (e.g., 15-30 minutes). The forming gas may include a mixture of nitrogen (N₂) and hydrogen (H₂) in a suitable ratio (e.g., 95:5, 90:10, etc.).

The process 800 may be performed iteratively to fabricate a suitable number of interconnect layers. For example, the process 800 may loop back to 810 after performing block 820 and may fabricate a second via layer on the metal layer fabricated at 820. In particular, a third dielectric layer of a third dielectric material may be fabricated. The third dielectric layer may be patterned to create one or more third vias. One or more suitable metallic materials may be deposited in the third vias to fabricate one or more metallic vias. An annealing process may then be carried out. A second metal layer may be fabricated on the second via layer in some embodiments. Additional layers of via layers and/or metal layers may be fabricated by performing blocks 810 and/or 820 iteratively.

FIG. 9A is a flow chart illustrating an example process 900 for fabricating an interconnect structure including a metallic via and a metallic pad in one process. FIGS. 9B-9G illustrate cross-sectional views of structures for fabricating an interconnect structure 990 by implementing process 900 in accordance with some embodiments of the present disclosure.

As shown, process 900 may start at 905 by fabricating a dielectric layer on a substrate. The substrate may be and/or include one or more transistors, interconnect layers, etc. Depositing the dielectric layer may involve depositing one or more interlayer dielectrics (ILDs), such as SiO₂, Si₃N₄, Al₂O₃, etc. For example, as shown in FIG. 9B, a dielectric layer 963 may be fabricated on a substrate 961. In some embodiments, a resist 965 may be fabricated on the dielectric layer 963.

At 910, the dielectric layer may be patterned and partially etched. That is, the dielectric layer is partially etched in depth. For example, as shown in FIG. 9C, a via 971 may be fabricated by partially etching the dielectric layer 963 and the resist 965.

At 915, the partially etched dielectric layer may be fully etched to create a via and/or a trench. The dielectric is fully etched in depth while maintaining an etching profile for via and trench due to the conformal etching. For example, as shown in FIG. 9D, a via 973 and a trench 975 may be created by etching the partially etched dielectric layer 963 and the resist 965. The resist 965 is removed after patterning the via 973 and the trench 975 is completed.

At 920, a barrier layer may be fabricated. For example, as shown in FIG. 9E, a barrier layer 967 (e.g., a layer including Ta or TaN) may be deposited on the fully etched dielectric layer and over the sidewalls of the via 973 and the trench 975.

At 925, a metal may be deposited to create a metallic via and a metallic pad. For example, a thin Cu seed layer may be deposited by physical vapor deposition (PVD) followed by the electroplating of Cu, which fills the via and the trench. The metal deposition may also create one or more metal wires. As shown in FIG. 9F, a metal may be deposited (e.g., by plating) in the via 973 and the trench 975 to create a metallic via 981 and a metallic pad 983, respectively.

At 930, a chemical mechanical polishing (CMP) process is performed. For example, the metallic via 981, the metallic pad 983, and metal wires (not shown) may be patterned and processed in the CMP process to remove excess Cu and planarize the surface, as shown in FIG. 9F. In some embodiments, as shown in FIG. 9G, a capping layer 969 (e.g., a SiN layer) may be deposited.

At 935, the metallic via and the metallic pad may be annealed. For example, the interconnect structure 990 of FIG. 9G may be annealed at the annealing temperatures (e.g., 350-450° C.) in a forming gas flow (e.g., a mixture of N₂ and H₂) for a suitable period of time (e.g., 15-30 minutes).

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events. In some embodiments, an etched surface and/or sidewall of the RRAM device may be cleaned prior to further processing.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. An apparatus, comprising:
a first interconnect layer fabricated on a substrate, wherein the first interconnect layer comprises a plurality of metallic interconnects;
a first resistive random-access memory (RRAM) device, comprising:
a first bottom electrode fabricated on a first metallic interconnect of the first interconnect layer;
a first top electrode; and
a first filament-forming layer fabricated between the first bottom electrode and the first top electrode, wherein the first filament-forming layer comprises a first switching oxide; and
a second RRAM device, comprising:
a second bottom electrode fabricated on a second metallic interconnect of the first interconnect layer;
a second top electrode; and
a second filament-forming layer fabricated between the second bottom electrode and the second top electrode, wherein the second filament-forming layer comprises a second switching oxide that is different from the first switching oxide.

2. The apparatus of claim 1, further comprising a first etch stop layer fabricated on the first interconnect layer, wherein a first filament-forming region of the first filament-forming layer and at least a portion of the first top electrode are fabricated in a first via in the first etch stop layer, and wherein a second filament-forming region of the second filament-forming layer and at least a portion of the second top electrode are fabricated in a second via in the first etch stop layer.

3. The apparatus of claim 2, wherein the first etch stop layer comprises at least one of silicon nitride or silicon oxynitride.

4. The apparatus of claim 1, wherein the first metallic interconnect is connected to a first transistor, and wherein the second metallic interconnect of the first interconnect layer is connected to a second transistor.

5. The apparatus of claim 1, wherein the first switching oxide comprises at least one of HfOₓ, TaOₓ, TiOₓ, NbOₓ, ZrOₓ, or SiO₂.

6. The apparatus of claim 5, wherein the first RRAM device further comprises an interface layer fabricated between the first top electrode and the first filament-forming layer, wherein the interface layer comprises at least one of Al₂O₃, MgO, Y₂O₃, or La₂O₃.

7. The apparatus of claim 1, wherein the first filament-forming layer does not include the second switching oxide.

8. The apparatus of claim 1, further comprising a second interconnect layer, wherein a first metallic interconnect of the second interconnect layer is fabricated on the first top electrode, and wherein a second metallic interconnect of the second interconnect layer is fabricated on the second top electrode.

9. The apparatus of claim 1, wherein the first top electrode is connected to a first bitline of a first crossbar circuit, and wherein the second top electrode is connected to a second bitline of a second crossbar circuit.

10. The apparatus of claim 1, wherein the first switching oxide comprises TaOx, and wherein the second switching oxide comprises HfOx.

11. The apparatus of claim 1, wherein the first bottom electrode and the second bottom electrode comprise the same metallic materials.

12. The apparatus of claim 1, further comprising a third RRAM device fabricated on a third interconnect layer.

13. A method, comprising:
fabricating a first bottom electrode of a first resistive random-access memory (RRAM) device and a second bottom electrode of a second RRAM device on a first metallic interconnect and a second metallic interconnect of a first interconnect layer, respectively, wherein the first metallic interconnect and the second metallic interconnect of the first interconnect layer are fabricated on a substrate;
fabricating a first filament-forming layer and a first top electrode on the first bottom electrode, wherein the first filament-forming layer comprises a first switching oxide; and
fabricating a second filament-forming layer and a second top electrode on the second bottom electrode, wherein the second filament-forming layer comprises a second switching oxide that is not included in the first filament-forming layer.

14. The method of claim 13, further comprising:
fabricating a first etch stop layer on the first interconnect layer and the substrate;
fabricating a first via in the first etch stop layer to expose a portion of the first bottom electrode; and
fabricating a second via in the first etch stop layer to expose a portion of the second bottom electrode, wherein at least a portion of the first filament-forming layer is fabricated in the first via, and wherein at least a portion of the second filament-forming layer is fabricated in the second via.

15. The method of claim 14, further comprising:
fabricating a dielectric layer in the second via, wherein one or more portions of the dielectric layer are fabricated on the first etch stop layer.

16. The method of claim 15, wherein fabricating the first filament-forming layer and the first top electrode on the first bottom electrode comprises:
fabricating a first switching oxide layer on the first etch stop layer, the exposed portion of the first bottom electrode, and the dielectric layer;
fabricating a first top electrode layer on the first switching oxide layer;
etching the first switching oxide layer; and
etching the first top electrode layer.

17. The method of claim 15, wherein the dielectric layer comprises silicon dioxide, and wherein the first etch stop layer comprises at least one of silicon nitride, silicon oxynitride.

18. The method of claim 15, wherein fabricating the second filament-forming layer and the second top electrode on the second bottom electrode comprises:
fabricating a second etch stop layer on the first top electrode;
removing the dielectric layer to expose the portion of the second bottom electrode;
fabricating a second switching oxide layer on the first etch stop layer, the second etch stop layer, and the exposed portion of the second bottom electrode;
fabricating a second top electrode layer on the second switching oxide layer; and
etching the second top electrode layer and the second switching oxide layer.

19. The method of claim 18, further comprising fabricating a third etch stop layer on the second top electrode layer.

20. The method of claim 13, wherein the first metallic interconnect and the second metallic interconnect are fabricated on a single substrate.
